(19) United States
(12) Patent Application Publication
(10) Pub. No.: US 2010/0229076 A1
(43) Pub. Date: Sep. 9, 2010

(54) Decoding Apparatus and Decoding Method

(76) Inventors: Masashi SHINAGAWA, Tokyo (JP); Makoto Noda, Tokyo (JP); Hiroyuki Yamagishi, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/699,604

(22) Filed: Feb. 3, 2010

(30) Foreign Application Priority Data
Mar. 4, 2009 (JP) P2009-050200

(51) Int. Cl. H03M 13/41; G06F 11/10

(52) U.S. Cl. 714/795; 714/E11.032

(57) ABSTRACT

Disclosed herein is a decoding apparatus including: with N and x each being a positive integer and k being a positive integer being equal to or greater than 1, a shift register of k stages configured to accumulate path select information for k inputs that is information about a survivor path of xN bits made up of radix-2^{x} in each transient state of a convolutional code of the number of states N; a path memory having one bank configured to store, at one address, the path select information for k inputs accumulated in the shift register; and a traceback circuit configured to trace back paths for m=rkx time in one clock by use of the path select information read from the path memory with t being a divisor of kx and r being 2 or 1/t.

### BACKGROUND OF THE INVENTION

1. Field of the Invention

The present invention relates to a decoding apparatus and a decoding method and, more particularly, to a decoding apparatus and a decoding method that are configured to be able to restrict the size of a memory for storing path select information for use in traceback processing and the latency involved in decoding processing.

2. Description of the Related Art

In the transmission of data from a transmitting apparatus to a receiving apparatus or from a recording apparatus to a reproducing apparatus in which the information recorded to a recording media by the recording apparatus is reproduced on the reproducing apparatus, for example, a data error may be caused on the transmission path between these apparatuses.

One of the typical methods of correcting errors caused on a transmission path is a convolutional code method. And Viterbi decoding is known for a method of realizing the maximum likelihood decoding of the convolutional code. Viterbi decoding is disclosed in A. J. Viterbi and J. K. Omura; Principles of Digital Communication and Coding, MacGraw-Hill, New York, 1979 below (hereinafter referred to as Non-Patent Document 1), for example.

Referring to FIG. 1, there is shown a block diagram of an exemplary configuration of a transmission/reception system.

A transmission/reception system shown in FIG. 1 is configured with a transmission apparatus 1 and a reception apparatus 3 being interconnected through a transmission path 2. The transmission apparatus 1 is configured by a convolutional encoder 11 and a transmission path encoder 12. The reception apparatus 3 is configured by a code detector 31, a transmission path decoder 32, and a Viterbi decoder 33. Information series subject to transmission is entered in the convolutional encoder 11 of the transmission apparatus 1.

The convolutional encoder 11 of the transmission apparatus 1 executes convolutional encoding processing on the entered information series and outputs a code series obtained by error correction encoding to the transmission path encoder 12.

The transmission path encoder 12 executes encoding processing such as modulation processing in accordance with the transmission path 2 and transmits obtained data to the reception apparatus 3 through the transmission path 2. The signal transmitted from the transmission path encoder 12 is inputted to the code detector 31 of the reception apparatus 3 via the transmission path 2.

The code detector 31 of the reception apparatus 3 detects data on the basis of the received signal and outputs the detected data to the transmission path decoder 32.

The transmission path decoder 32 executes decoding processing such as demodulation processing on the data supplied from the code detector 31 and outputs an obtained reception sequence to the Viterbi decoder 33.

The Viterbi decoder 33 executes Viterbi decoding processing on the reception sequence supplied from the transmission path decoder 32 and outputs a decoded sequence obtained by error correction as a decoding result.

The following briefly explains the principles of Viterbi decoding.

A conditional probability (likelihood function) P₀(V|W) with a reception sequence at the time of the transmission of a certain code sequence W being V is expressed in equation (6) below.

$${P}_{0} ( V \vert W ) = {\prod }_{i = 0}^{S - 1} P ( {v}_{i} \vert {w}_{i} ) \qquad ( 6 )$$

In equation (6), S is indicative of the number of reception sequences, vᵢ is indicative of an ith reception signal, and wᵢ is indicative of ith transmission signal in a certain code sequence W. P(vᵢ|wᵢ) becomes a conditional probability with a reception signal at the time of the transmission of wᵢ being vᵢ. Maximum likelihood decoding is executed by obtaining a code sequence that maximizes this P₀(V|W).

−logₑP(vᵢ|wᵢ) is called a branch metric. A sum of branch metrics for code sequences W corresponding to a certain path, namely, −logₑP(V|W), is called a path metric.

Referring to FIG. 2, there is shown a block diagram illustrating an exemplary configuration of the Viterbi decoder 33 that realizes maximum likelihood decoding on the basis of a trellis diagram.

As shown in FIG. 2, the Viterbi decoder 33 is configured by a branch metric calculator 41, an ACS (Add Compare Select) processing unit 42, a path metric memory 43, and a survivor path processing unit 44. Let the constraint length of the convolutional encoder 11 be K, then the number of states N in the trellis diagram is expressed by N=2^{K-1}, where K and N are positive integers.

The branch metric calculator 41 calculates a branch metric for each of the reception signals constituting a reception sequence and outputs an obtained branch metric to the ACS processing unit 42.

The ACS processing unit 42 references the branch metric obtained by the branch metric calculator 41 to determine a survivor path of each state in accordance with a trellis diagram of the number of states determined by the constraint length of the convolutional encoder 11. The survivor path is a path selected on the basis of a Hamming distance from among two or more paths connecting a state with a pre-state connected to that state.

Further, the ACS processing unit 42 outputs path select information that is survivor path information to the survivor path processing unit 44 to store the path select information in a path memory 44A in the survivor path processing unit 44. Upon outputting path select information to the survivor path processing unit 44, the ACS processing unit 42 updates a value of the path metric memory 43 that is a memory for storing the metric of each state.

On the basis of the path select information stored in the path memory 44A, the survivor path processing unit 44 selects a path (maximum likelihood path) having a smallest path metric from among the surviving paths for the states at the time the input of a reception sequence has ended. The value corresponding to the state on the maximum likelihood path selected by the survivor path processing unit 44 is outputted as a decoded sequence, which realizes the maximum likelihood decoding.

Now, it should be noted that, if a reception sequence is relatively long, this length increases a path memory length that is a length of path select information held in the path memory until a maximum likelihood path is selected or a time (latency) required for decoding. Therefore, normally, the path memory is used by truncating the path memory length to a length that little affects decoding characteristic. Generally, as constraint length K and coding ratio of the convolutional encoder increases, it is necessary to allocate a greater path memory length.

For methods of selecting a maximum likelihood path from path select information stored in a path memory, a traceback method and a register exchange method are known.

The register exchange method is simple in circuit configuration for a high-speed operation, but has a characteristic that, as a path memory length increases, a circuit scale and power consumption grow. Therefore, if a path memory length is relatively long, the traceback method is often used in which a RAM (Random Access Memory) is used to store information about survivor paths and this information is traced back by the amount of the path memory length to select a maximum likelihood path.

Here, let a traceback length that is a length of the path memory to be traced back in the traceback method be T. Also assume that an input to the Viterbi decoder be configured by radix-2^{x}. Note that T and x are positive integers.

G. Feygin and P. G. Gulak, “Architectural Tradeoffs for Survivor Sequence Memory Management in Viterbi Decoders,” IEEE Transactions on Communications, vol. 41, no. 3, pp. 425-429, March 1993 (hereinafter referred to as Non-Patent Document 2) proposes a k-pointer algorithm and one-pointer algorithm as traceback algorithms. R. Cypher and C. B. Shung, “Generalized Trace Back Techniques for Survivor Memory Management in the Viterbi Algorithm,” IEEE Global Telecommunications Conference and Exhibition. ‘Communications: Connecting the Future,’ vol. 2, pp. 1318-1322, December 1990 (hereinafter referred to as Non-Patent Document 3) proposes a hybrid algorithm obtained by combining these two algorithms.

In the k-pointer algorithm, the RAM for use in path memory is divided into 2 k banks of bit width xN and depth T/{x·(k−1)} and, by use of k read pointers, k locations are read in parallel for one writing. Here, k is a positive integer greater than 1 and indicative of the number of operations for reading from the path memory RAM necessary for the traceback method.

In the one-pointer algorithm, the RAM is divided into (k+1) banks of bit width xN and depth T/{x·(k−1)} and reading is executed at a speed k times a writing speed, thereby executing reading of k times for one writing.

In the hybrid algorithm, by use of positive integers k₁ and k₂ satisfying k=k₁k₂, reading operations at k locations are executed in parallel by use of k₂ read pointers at a speed of k₁ times a write speed.

P. J. Black and T. H.-Y. Meng, “Hybrid Survivor Path Architectures for Viterbi Decoders,” ICASSP, vol. 1, pp. 433-436, April 1993 (hereinafter referred to as Non-Patent Document 4) proposes a hybrid pretraceback algorithm for realizing a memory configuration and latency similar to those of the one-pointer algorithm by executing one write operation for k inputs by use of a pretraceback circuit.

In the hybrid pretraceback algorithm, the path select information outputted from the ACS processing unit is sorted by use of the pretraceback circuit before writing the path select information to the path memory, thereby decreasing the load at the time of traceback processing. The pretraceback circuit has a register exchange configuration of k stages.

T. Miyauchi and M. Hattori, “Viterbi Decoding Apparatus and Viterbi Decoding Method,” U.S. Pat. No. 6,651,215 B2, Sony Corporation, Nov. 18, 2003, Filed Dec. 17, 1998 (hereinafter referred to as Patent Document 1) proposes a method in which reading of k locations for one write operation is realized by use of k dual port RAMS of 1-write port and 1-read port as a path memory, thereby executing traceback operations for kx time with one clock. This method enables the reduction of the RAM size.

M. Rim and Y. Oh, “Traceback-Performing Apparatus in Viterbi Decoder,” U.S. Pat. No. 6,712,880, Samsung Electronics Co., Ltd., Jan. 27, 1998, Filed Nov. 14, 1995 (referred to as Patent Document 2) proposes configuration in which a bank is shared for writing in the k-pointer algorithm and reading for decoding, thereby saving one bank to realize the division into (2k−1) banks. This configuration enables a memory management that is simple in RAM address specification.

Table 1 below shows relations between path memory size M and latency L of a survivor path processing unit at the time when the above-mentioned algorithms of the related-art traceback method. Latency L is a time from first entering of path select information into the survivor path processing unit to outputting of a first decoding result with a time interval for the ACS processing unit to output path select information of xN bits being 1.

TABLE 1

| Algorithm | M [bit] | L |
|---|---|---|
| One-pointer | $\frac{k + 1}{k - 1} \cdot TN$ | $\frac{k + 1}{k - 1} \cdot \frac{T}{x}$ |
| k-pointer | $\frac{2 k}{k - 1} \cdot TN$ | $\frac{2 k}{k - 1} \cdot \frac{T}{x}$ |
| Hybrid | $\frac{( {k}_{1} + 1 ) \cdot {k}_{2}}{{k}_{1} {k}_{2} - 1} \cdot TN$ | $\frac{( {k}_{1} + 1 ) \cdot {k}_{2}}{{k}_{1} {k}_{2} - 1} \cdot \frac{T}{x}$ |
| Pretrace-back | $( \frac{k + 1}{k - 1} \cdot T + kx ) \cdot N$ | $\frac{k + 1}{k - 1} \cdot \frac{T}{x}$ |
| Patent Document 1 | 2TN | $( \frac{T}{x} + k ) \cdot ( \frac{1}{k} + 1 )$ |
| Patent Document 2 | $\frac{( 2 k - 1 )}{k - 1} \cdot TN$ | $\frac{2 k}{k - 1} \cdot \frac{T}{x}$ |

FIG. 3 shows changes of M when k is changed with T=112 and x=2. FIG. 4 shows changes of L.

Although not shown in FIG. 3 and FIG. 4, the values of M and L of the hybrid algorithm are equal to or higher than the values of M and L of the one-pointer algorithm and equal to or lower than the values of M and L of k-pointer algorithm depending on the values of k₁ and k₂ satisfying k=k₁k₂. For example, the values of M and L of the hybrid algorithm match the values of k-pointer algorithm if k₁=1 and the values of one-pointer algorithm if k₂=1.

It should be noted that the value of M of the pretraceback algorithm shown in Table 1 and FIG. 3 is obtained by considering the memory size of the pretraceback circuit in addition to the memory size of the path memory.

For more information, refer to S. Thurnhofer, “Traceback Buffer Management for VLSI Viterbi Decoders.” U.S. Pat. No. 6,601,215 B1, Agere Systems Inc., Jul. 29, 2003, Filed Feb. 1, 2000 (hereinafter referred to as Patent Document 3).

### SUMMARY OF THE INVENTION

According to the algorithms of the related-art traceback method, the values of memory size M and latency L can be made smaller by increasing the value of k as seen from each equation listed in Table 1.

However, as the value of k increases, the number of banks of the path memory also increases, thereby increasing the circuit scale of peripheral circuits such as a selector for selecting information read from these banks and a controller.

Hence, the value of k is often set below 3; in such a case, memory size M of the path memory needs to be 2TN bits or more. Generally, as the value of N increases, a greater traceback length T is required, thereby increasing the circuit scale of a path memory of 2TN-bit size.

Also, a configuration such as proposed in Patent Document 1 in which traceback processing for kx time is executed in 1 clock increases the processing operations that must be completed within 1 clock if the value of k is large, thereby making difficult operations at high clock frequencies.

Therefore, such an algorithm of the traceback method is desired as one that is as small as possible in memory size and circuit scale including peripheral circuits and operable at high clock frequencies. Besides, if a short processing time is required as with wireless communication systems, an algorithm making the latency of decoding as small as possible is required.

Therefore, the present invention addresses the above-identified and other problems associated with related-art methods and apparatuses and solves the addressed problems by providing a decoding apparatus and a decoding method that minimize the size of a memory in which path select information for use in traceback processing and the latency involved in decoding.

In carrying out the invention and according to one mode thereof, there is provided a decoding apparatus. This decoding apparatus has, with N and x each being a positive integer and k being a positive integer being equal to or greater than 1, a shift register of k stages configured to accumulate path select information for k inputs that is information about a survivor path of xN bits made up of radix-2^{x} in each transient state of a convolutional code of the number of states N; a path memory having one bank configured to store, at one address, the path select information for k inputs accumulated in the shift register; and a traceback circuit configured to trace back paths for m=rkx time in one clock by use of the path select information read from the path memory with t being a divisor of kx and r being 2 or 1/t.

In the above-mentioned decoding apparatus, a traceback length of the one traceback circuit is represented by positive integer T divisible by kx; the number of clocks necessary for one traceback processing operation is represented by l in the case where next traceback processing is started every s times the path select information is written to the path memory; α=T/(kx); and ceiling (b) represents a minimum integer equal to or higher than real number b, then, s and l are expressed by equation (1) and equation (2) below respectively;

$$\begin{matrix}s ≧ \{ \begin{matrix}ceiling ( \frac{α - 1}{2 \cdot ( k - 1 )} ) , & if r = 2 \\ ceiling ( \frac{α}{rk - 1} ) and & k > \frac{1}{r} , else\end{matrix} & ( 1 ) \\ l = \{ \begin{matrix}ceiling ( \frac{α + 2 s - 1}{2} ) , & if r = 2 \\ \frac{α + s}{r} , & else\end{matrix} & ( 2 )\end{matrix}$$

and the traceback circuit executes one traceback processing operation for (T+skx) by taking a time equivalent to l clocks, thereby outputting a decoding result of skx bits.

In the above-mentioned decoding apparatus, a traceback length of the two traceback circuits is represented by positive integer T divisible by kx; the number of clocks necessary for one traceback processing operation is represented by l in the case where next traceback processing is started every s times the path select information is written to the path memory; α=T/(kx); u represents a positive integer satisfying u s; and ceiling (b) represents a minimum integer equal to or higher than real number b, then, s and l are expressed by equation (3) and equation (4) below respectively;

$$\begin{matrix}s ≧ ( \frac{α - r \cdot \{ ( k - 1 ) \cdot u + 1 \}}{rk - 1} ) and k > \frac{1}{r} and r ≦ 1 & ( 3 ) \\ l = \frac{α + s}{r} + u - 1 & ( 4 )\end{matrix}$$

and the traceback circuit executes one traceback processing operation for (T+skx) by taking a time equivalent to l clocks, thereby outputting a decoding result of skx bits.

In the above-mentioned decoding apparatus, depth a of a RAM (Random Access Memory) configuring the path memory is represented by equation (5);

$$a = α + s + ceiling ( \frac{l}{k} ) - 1. \qquad ( 5 )$$

In the above-mentioned decoding apparatus, if r=2 or the number of the traceback circuits is two, the path memory is configured by a dual-port RAM having two read ports.

In the above-mentioned decoding apparatus, if r≦1 and s=1, then the path memory is configured by a single-port RAM.

In the above-mentioned decoding apparatus, the path memory is configured by a RAM that executes an operation of outputting write information written immediately before from a read port at a time next to a time at which writing was executed.

In the above-mentioned decoding apparatus, a value of m is restricted with a maximum value of m being m_{fc} and, for values of k and r, values satisfying m≦m_{fc} are used.

In the above-mentioned decoding apparatus, for values of k and r, values are used that minimize a sum of a circuit scale of the shift register and a circuit scale of a RAM for use in the path memory.

In the above-mentioned decoding apparatus, for values of k and r, values are used that minimize a sum of a circuit scale of the shift register, a circuit scale of a RAM for use in the path memory, and a circuit scale of a flip-flop for holding information read from the path memory arranged in a module including the traceback circuit.

In the above-mentioned decoding apparatus, the sift register is a pretraceback circuit of k stages.

In carrying out the invention and according to another mode thereof, there is provided a decoding method. This decoding method has the steps of: with N and x each being a positive integer and k being a positive integer being equal to or greater than 1, accumulating, by a shift register of k stages, path select information for k inputs that is information about a survivor path of xN bits made up of radix-2^{x} in each transient state of a convolutional code of the number of states N; storing, by a path memory having one bank, at one address, the path select information for k inputs accumulated in the shift register; and tracing back, by a traceback circuit, paths for m=rkx time in one clock by use of the path select information read from the path memory with t being a divisor of kx and r being 2 or 1/t.

In one mode of the present invention, path select information that is information about a survivor path of xN bits made up of radix-2^{x} in each transient state of a convolutional code of the number of states N is accumulated by a shift register of k stages by k inputs. The path select information for k inputs accumulated in the shift register is stored by a path memory having one bank, at one address. Further, paths for m=rkx time are traced back by a traceback circuit in one clock by use of the path select information read from the path memory with t being a divisor of kx and r being 2 or 1/t, thereby outputting a decoding result.

As described above and according to one mode of the invention, the size of a memory for use in storing path select information for use in traceback processing and the latency involved in decoding can be significantly restricted low.

### BRIEF DESCRIPTION OF THE DRAWINGS

Other features and advantages of the invention will become apparent from the following description of embodiments with reference to the accompanying drawings in which:

FIG. 1 is block diagram illustrating an exemplary configuration of a transmission/reception system;

FIG. 2 is a block diagram illustrating an exemplary configuration of a Viterbi decoder;

FIG. 3 is a diagram illustrating the change of M at the time when k is changed with T=112 and x=2;

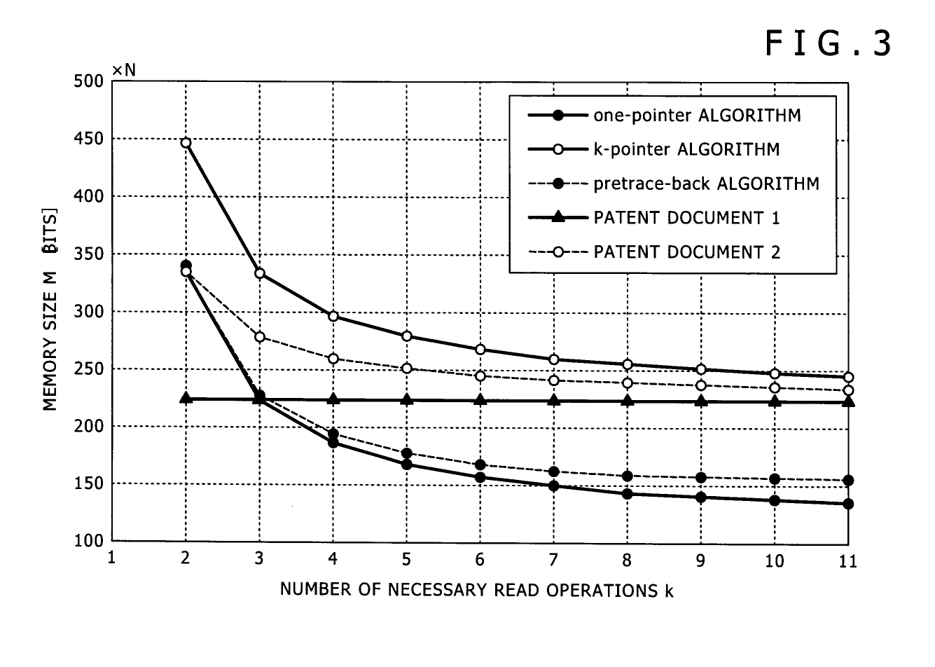

FIG. 4 is a diagram illustrating the change of L at the time when k is changed with T=112 and x=2;

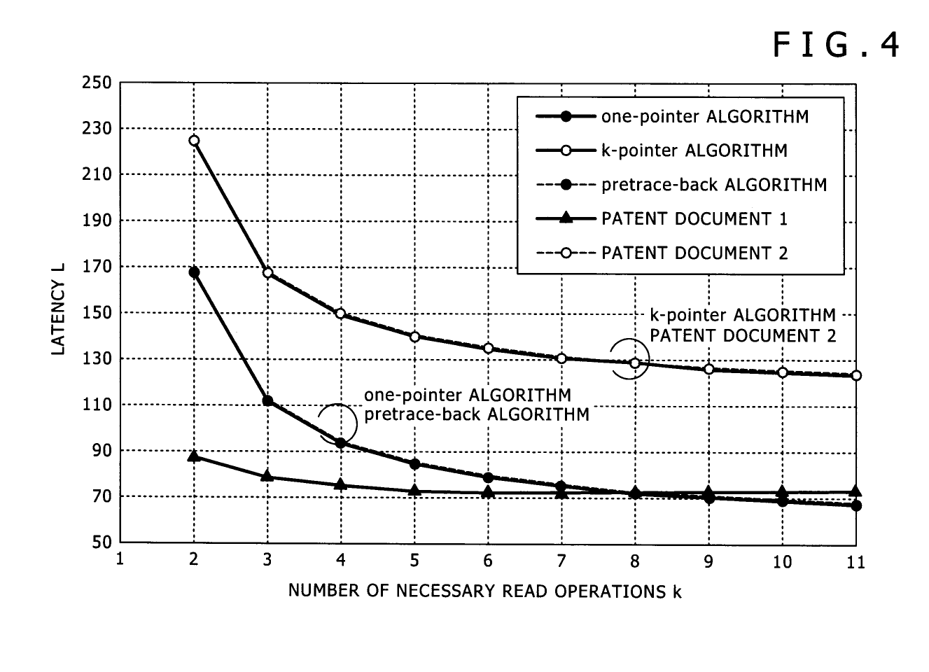

FIG. 5 is a block diagram illustrating an exemplary configuration of a reception apparatus practiced as one embodiment of the present invention;

FIG. 6 is a block diagram illustrating an exemplary basic configuration of a survivor path processing unit;

FIG. 7 is a diagram illustrating an exemplary configuration of a path memory RAM;

FIG. 8 is a diagram illustrating the change of M at the time when k is changed with r=2 in the case where T=112 and x=2;

FIG. 9 is a diagram illustrating the change of L at the time when r=2 in the case where T=112 and x=2;

FIG. 10 is a flowchart indicative of a decision procedure for deciding configurational parameters of a survivor path processing unit;

FIG. 11 is a flowchart indicative of a procedure of computation to be executed in step S2 shown in FIG. 10;

FIG. 12 is a flowchart indicative of a procedure of decision to be executed in step S0 shown in FIG. 10;

FIG. 13 is a block diagram illustrating an exemplary configuration of a survivor path processing unit;

FIG. 14 is a memory access chart of a path memory RAM shown in FIG. 13;

FIG. 15 is a block diagram illustrating another exemplary configuration of a survivor path processing unit;

FIG. 16 is a block diagram illustrating still another exemplary configuration of a survivor path processing unit;

FIG. 17 is a memory access chart of a path memory RAM shown in FIG. 16;

FIG. 18 is a diagram illustrating an exemplary layout of a path memory RAM;

FIG. 19 is a flowchart indicative of an exemplary variation of the decision procedure to be executed in step S0 shown in FIG. 10;

FIG. 20 is a flowchart indicative of another exemplary variation of the decision procedure of k and r to be executed in step S0 shown in FIG. 10;

FIG. 21 is a block diagram illustrating an exemplary configuration of a survivor path processing unit;

FIG. 22 is a memory access chart of a path memory RAM shown in FIG. 21;

FIG. 23 is a diagram illustrating an exemplary configuration of a convolutional encoder;

FIG. 24 is a trellis diagram indicative of a sequence to be encoded by the convolutional encoder shown in FIG. 23;

FIG. 25 is a block diagram illustrating an exemplary configuration of a survivor path processing unit; and

FIG. 26 is a memory access chart of a path memory RAM shown in FIG. 25.

### DETAILED DESCRIPTION OF THE PREFERRED EMBODIMENTS

This invention will be described in further detail by way of embodiments thereof with reference to the accompanying drawings.

### <Exemplary Configuration of a Reception Apparatus>

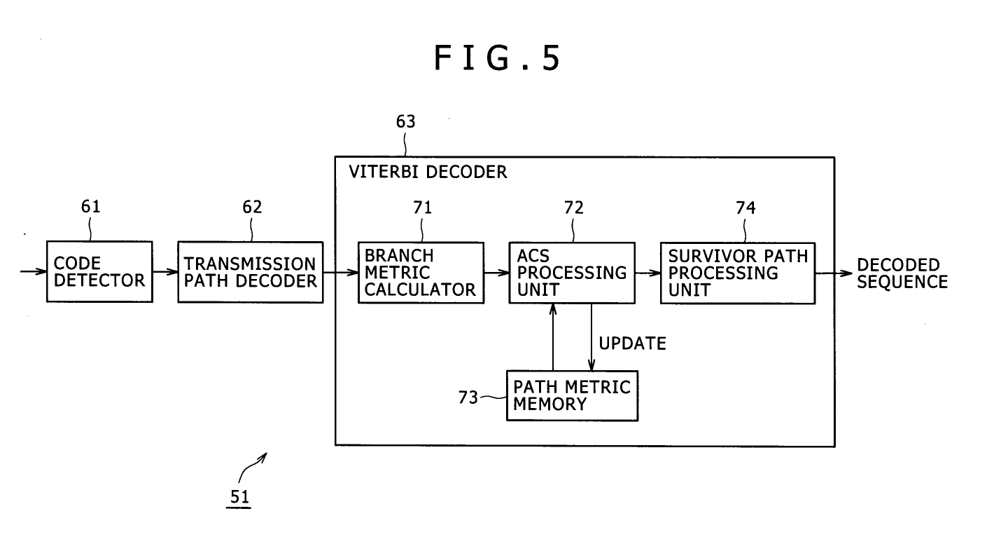

Referring to FIG. 5, there is shown an exemplary configuration of a reception apparatus 51 practiced as one embodiment of the present invention.

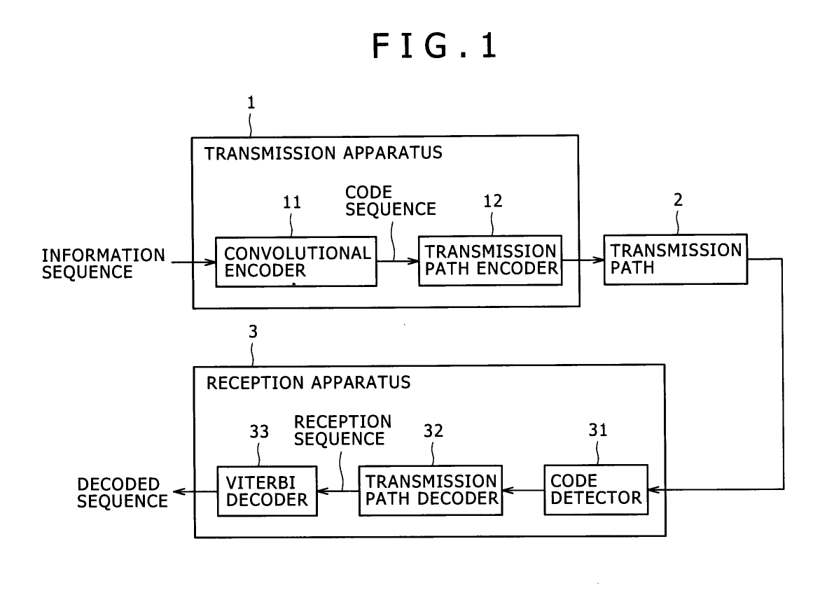

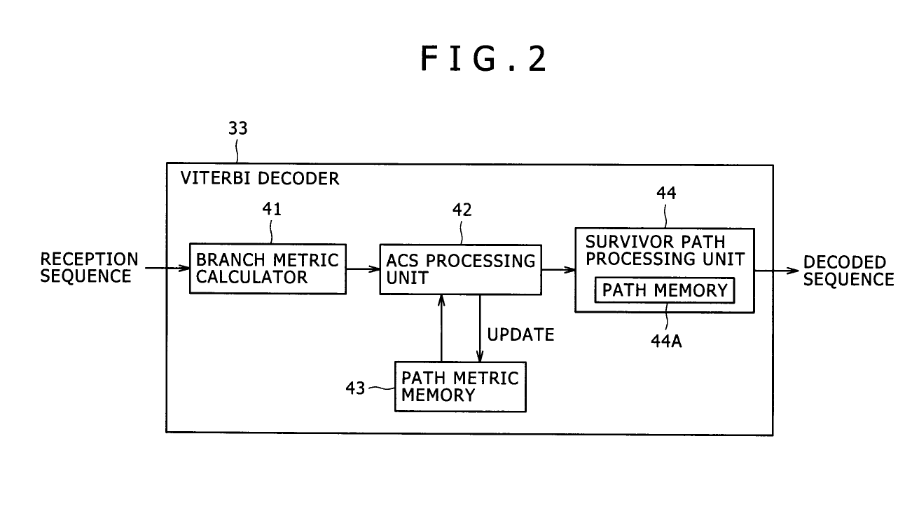

The configuration of the reception apparatus 51 shown in FIG. 5 is substantially the same as a configuration obtained by combining a configuration of a reception apparatus shown in FIG. 1 and FIG. 2. Therefore, a description of the overlapping parts is omitted appropriately.

A code detector 61 of the reception apparatus 51 outputs data detected on the basis of a received signal to a transmission path decoder 62.

The transmission path decoder 62 executes decoding processing on the data supplied from the code detector 61 and outputs an obtained reception sequence to a Viterbi decoder 63.

The Viterbi decoder 63 is configured by a branch metric calculator 71, an ACS processing unit 72, a path metric memory 73, and a survivor path processing unit 74. The reception sequence outputted from the transmission path decoder 62 is entered in the branch metric calculator 71.

The branch metric calculator 71 calculates a branch metric for each received signal configuring a reception sequence and outputs an obtained branch metric to the ACS processing unit 72.

The ACS processing unit 72 determines a survivor path of each state and outputs obtained path select information to the survivor path processing unit 74. Also, the ACS processing unit 72 updates the value of the path metric memory 73.

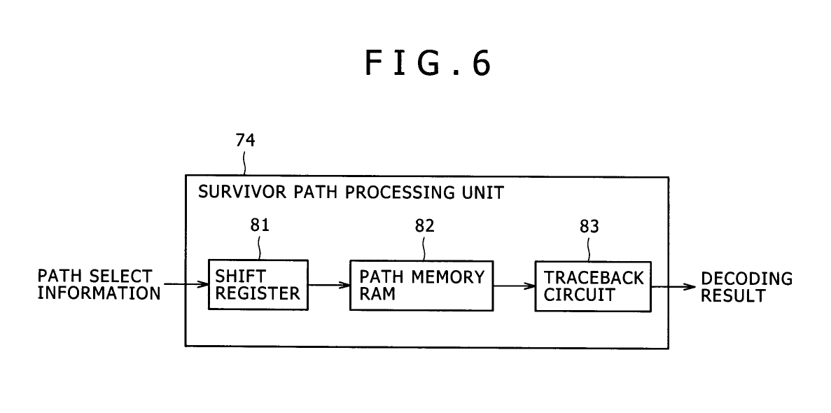

Referring to FIG. 6, there is shown a block diagram illustrating an exemplary basic configuration of the survivor path processing unit 74.

Details of a configuration of the survivor path processing unit 74 will be described later. As shown in FIG. 6, the survivor path processing unit 74 is configured by a shift register 81, a path memory RAM 82, and a traceback circuit 83. In the shift register 81, path select information configured by radix-2^{x} is entered, each xN bits per clock. In each block of the survivor path processing unit 74, a clock of the same frequency is entered, on the basis of which each operation of these blocks is executed.

The shift register 81 accumulates k clocks of the entered path select information and collectively writes the path select information of k×N bits to one address of the path memory RAM 82.

The path memory RAM 82 stores the path select information supplied from the shift register 81.

The traceback circuit 83 executes traceback processing on the basis of the path select information stored in the path memory RAM 82 when the input of the reception sequence has been completed by the number enough for starting traceback processing, thereby selecting a maximum likelihood path. The survivor path processing unit 74 outputs a value corresponding to a state on the maximum likelihood path as a decoded sequence.

### An Address Configuration of the Path Memory RAM

State number N, traceback length T, and x are predetermined in accordance with the error ratio performance and the throughput required in each system to be realized. N and x are positive integers and k is a positive integer greater than 1. T is a positive integer that can be divided by kx.

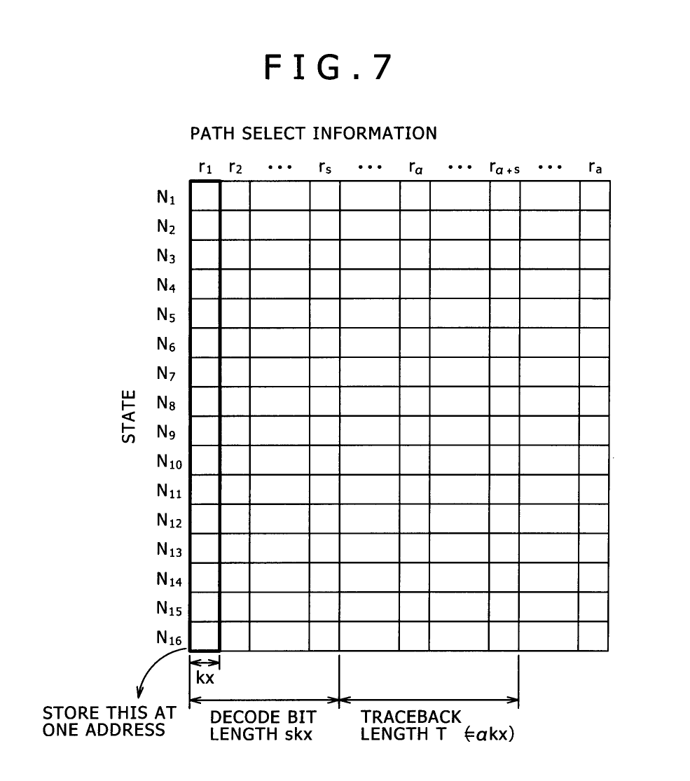

Referring to FIG. 7, there is shown an exemplary configuration of the path memory RAM 82.

In the example shown in FIG. 7, path select information rₗ through rₐ are indicated in the horizontal direction. State number N is 16; states N₁ through N₁₆ are indicated in the vertical direction.

In each box, a value of kx bits corresponding to path select information is stored. In the survivor path processing unit 74 where path select information of k×N bits is collectively stored, path select information for kx time is stored at one address of the path memory RAM 82.

Further, α is defined as shown in equation (7) below.

$$α := \frac{T}{kx} \qquad ( 7 )$$

Because path select information for kx time per address is stored, α is indicative of the number of addresses of the path memory RAM 82 necessary for storing path select information for T time. T can be divided by kx, so that α is always a positive integer.

Writing of path select information to one address or reading of path select information from one address is executed by use of one port. If the path memory RAM 82 is a single-port RAM, only one of writing and reading can be executed at a time. In contrast, if the path memory RAM 82 is a dual-port RAM in which one write port and one read port are provided, both writing and reading can be executed at a time.

Also, if the path memory RAM 82 is a dual-port RAM in which two read ports are provided, path select information can be also executed collectively for two addresses at a time.

It should be noted that, in the example shown in FIG. 7, traceback processing that traces back a survivor path starts when path select information has been accumulated up to r_{α+s}. Executing traceback processing in which path select information r_{α+s}, r_{α+s-1}, . . . , r_{α}, . . . , rₛ, . . . , r₂, r₁ are read provides a decoding result of skx bits. S is a positive integer.

Further, unlike a path memory used in related-art algorithms, the path memory RAM 82 is not used by dividing into two or more banks but is configured by a RAM having a single bank. Therefore, if the value of k is increased, a peripheral circuit such as a selector need not be arranged, so that the increasing does not involve the increase in circuit scale. If two or more banks are configured in the path memory as described above, a peripheral circuit such as a selector is required for selecting read data.

It should be noted that, if the width of k×N bits that is a unit in which path select information is written is large and a RAM having this bit width cannot be prepared, the pass selection information of k×N bits may be divided to be stored in two or more RAM.

In this case, executing writing and reading on all of two or more RAMs at a same address and with a same timing allows the use of two or more RAMs as one RAM in an equivalent manner. Consequently, the path memory RAM 82 comes to be configured by two or more RAMs, but, in terms of operation, these RAMs may be regarded as one RAM, so that the number of banks may be said to be one.

### Traceback Processing by Use of Path Select Information

The traceback circuit 83 executes traceback processing by tracing back paths for m time in one clock. m is expressed by equation (8) below.

m=rkx (8)

In equation (8) above, the value of r is 2 or 1/t,

where t is a divisor of kx.

If r=2, then m=2 kx and traceback processing is executed by tracing back paths for 2 kx in one clock. Because the path select information for kx time per address is stored in the path memory RAM 82, traceback processing requires to read the path select information from two addresses in one clock.

Therefore, if r=2, a dual-port RAM having two read ports is used for the path memory RAM 82. It should be noted, however, that, if writing is executed during the reading of path select information by use of the two ports, one of the ports must be used for writing. If this happens, reading can be executed only from the other port.

On the other hand, if the value of r is 1/t and r≦1, then traceback processing is executed by tracing back paths for kx/t time in one clock. The traceback processing of the path select information for kx time is executed in t clocks. In traceback processing, the path select information stored at one address may only be read in one clock.

If r≦1, a dual port RAM having two ports may also be used as the path memory RAM 82. In this case, even if writing is executed during the reading of path select information, the reading may be continued by use of the other port. Because reading and writing of path select information can be executed independently, the reading of path select information is not affected by the writing.

Next, let the number of decoded bits obtained by one session of traceback processing be skx bits by use of positive integer s. After the path select information for (T+skx) has been written to the path memory RAM 82, the traceback circuit 83 starts traceback processing. In the traceback processing to be executed by the traceback circuit 83, the path select information for (T+skx) written to the path memory RAM 82 is sequentially read to trace back paths, thereby obtaining a skx-bit decoding result.

As described above, the path select information for kx time is written to one address of the path memory RAM 82, so that the path select information for (T+skx) is stored at (α+s) addresses. In order to read the path select information for (T+skx) for executing traceback processing, (α+s) read operations are necessary.

Subsequently, every time the path select information is written to the path memory RAM 82 s times, next traceback processing is started by the traceback circuit 83.

The last one write operation of s write operations provides information that is used first in the traceback operation that is started immediately after the s write operations. Therefore, a RAM in which a write-first operation in which, after a write operation, write information written immediately before is outputted from that read port is executed may be used as the path memory RAM 82. Also, as will be described later, a delay element may be used to use delayed write information first in traceback processing.

As described above, if path select information is entered every clock, writing to the path memory RAM 82 is executed every k clocks in the survivor path processing unit 74, thereby starting traceback processing every s write operations. In order to end one traceback processing operation during sk clocks that provide a duration of time up to the start of next traceback processing, it is required to read path select information for (T+skx) and write path select information s times during sk clocks.

Therefore, r and s must satisfy a relation indicated by equation (9) below. From equation (9), s is expressed by equation (10) below. Function ceiling (b) is indicative of a minimum integer among the integers in excess of real number b.

$$\begin{matrix}\{ \begin{matrix}sk [ clock ] ≧ \frac{α + 2 s - 1}{2} , & if r = 2 \\ sk [ clock ] ≧ \frac{α + s}{r} , & else\end{matrix} & ( 9 ) \\ s ≧ \{ \begin{matrix}ceiling ( \frac{α - 1}{2 \cdot ( k - 1 )} ) , & if r = 2 \\ ceiling ( \frac{α}{rk - 1} ) and k > \frac{1}{r} , & else\end{matrix} & ( 10 )\end{matrix}$$

The path select information for (T+skx) is read to execute traceback processing by taking l clocks, thereby providing a decoding result of skx bits. The number of clocks l necessary for traceback processing is expressed by equation (11) below.

$$l = \{ \begin{matrix}ceiling ( \frac{α + 2 s - 1}{2} ) , & if r = 2 \\ \frac{α + s}{r} , & else\end{matrix} \qquad ( 11 )$$

Further, let the number of traceback circuits 83 for tracing back paths for m time in one clock be p. As will be described later, it is also practicable to provide two or more traceback circuits to configure the survivor path processing unit 74.

While one traceback operation is executed over l clocks, writing to the path memory RAM 82 is executed every k clocks, so that the number of addresses of the path memory RAM 82 is increased by ceiling (l/k)−1. This prevents the path select information for use in traceback processing from being overwritten before the path select information is read.

The number of addresses (depth) a of the path memory RAM 82 is expressed by equation (12) below.

$$a = α + s + ceiling ( \frac{l}{k} ) - 1 \qquad ( 12 )$$

Thus, memory size M arranged in the survivor path processing unit 74 is expressed by equation (13) below and latency L is expressed by equation (14) below. M in equation (13) is equivalent to a value obtained by adding memory size akxN of the path memory RAM 82 to memory size kxN of the shift register 81.

M=(a+1)·kxN (13)

L=(α+s)·k+l (14)

Memory size M and latency L of the survivor path processing unit 74 are summarized, in correspondence to Table 1, as shown in Table 2.

TABLE 2

| Algorithm | M [bit] | L |
|---|---|---|
| Configuration according to | (a + 1) · k × N | (α + s) · k + l |
| the present invention | | |

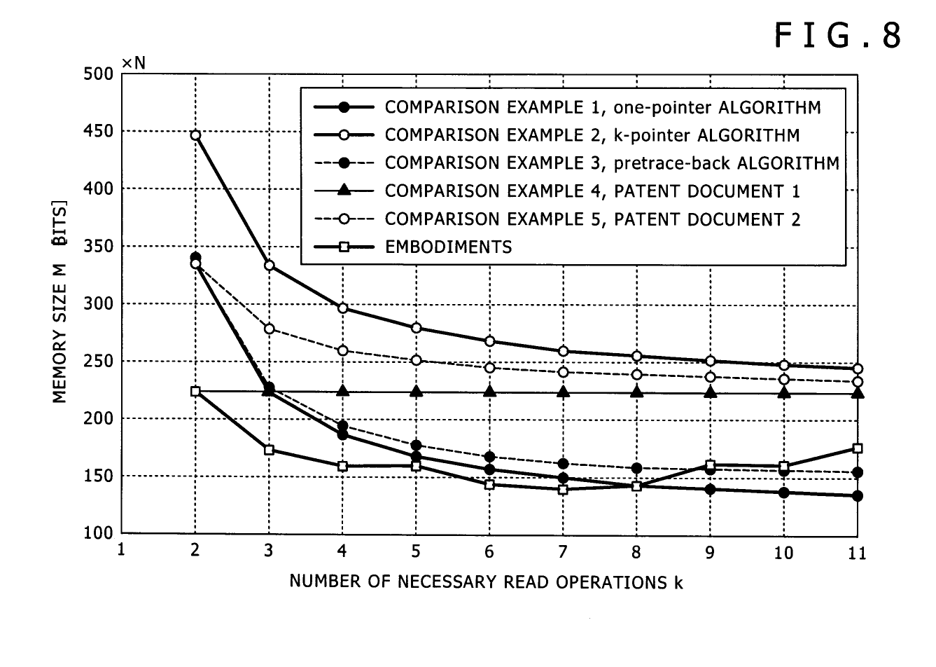

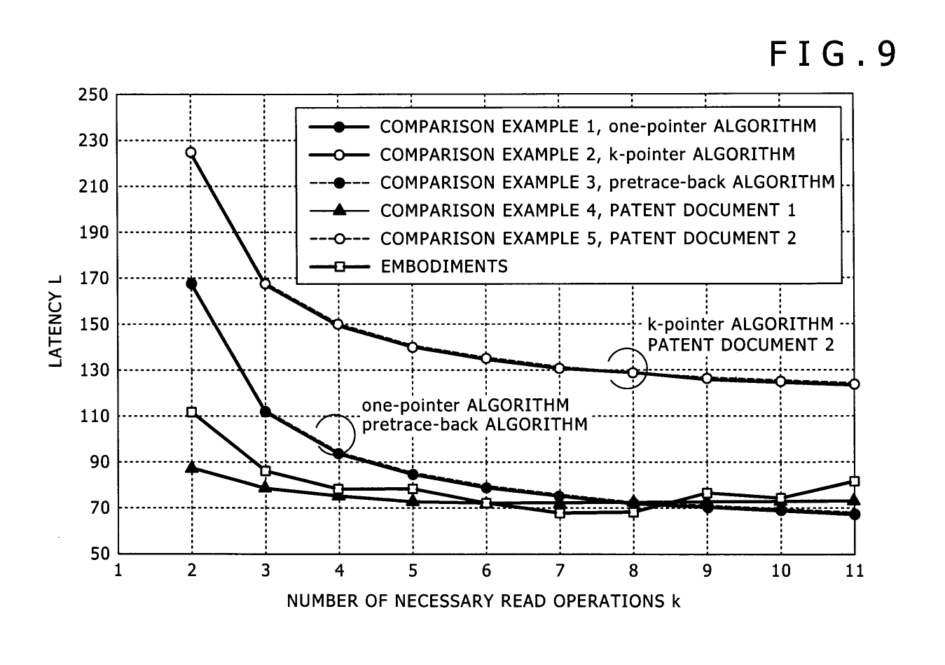

Also, with T=112 and x=2, memory size M of the survivor path processing unit 74 obtained by changing the value of k with r=2 is shown in FIG. 8 and latency L is shown in FIG. 9. FIG. 8 and FIG. 9 show results obtained by calculation with a minimum integer exceeding 112 and divisible by kx being T if traceback length T=112 cannot be divided by kx.

According to the above-mentioned configuration of the survivor path processing unit 74, reduction of memory size and latency of about 23% can be obtained as compared with the one-point algorithm and the pretraceback algorithm when k is set to 3 as ordinarily used. Further, according to the above-mentioned configuration of the survivor path processing unit 74, the latency increases by about 9% as compared with the algorithm proposed in Patent Document 1, but the memory size can be reduced by about 23% as compared with that algorithm. A decision procedure for parameters configuring the survivor path processing unit

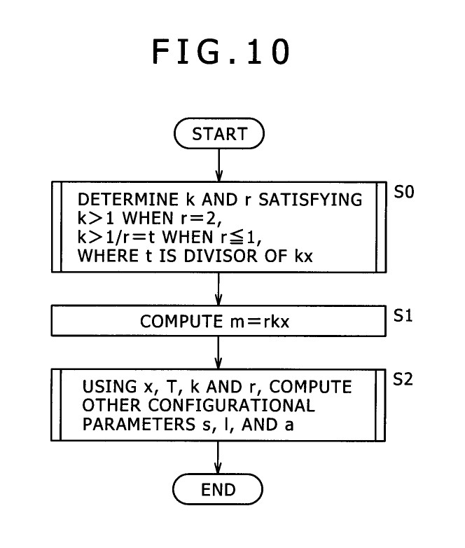

Referring to the flowchart shown in FIG. 10, the following describes a procedure of determining the parameters configuring the survivor path processing unit 74.

Following this procedure, each of the configurational parameters is determined at the time of design or the like timing of the reception apparatus 51 and the survivor path processing unit 74 is generated that is specified by the determined configurational parameters.

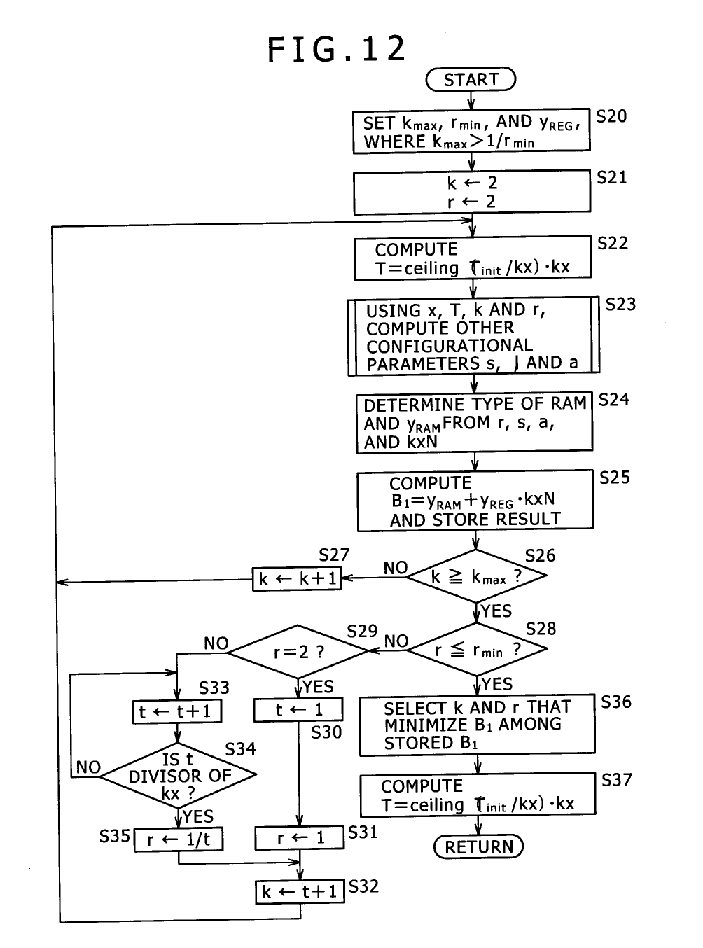

In step S0, a value of r with 2 or 1/t and a value of positive integer k satisfying k>1 when r=2 and k>1/r=t when r≦1, where t is a divisor of kx. A decision procedure of r and k will be described with reference to the flowchart shown in FIG. 12.

In step S1, by use of the values of r and k determined in step S0, a value of m is computed in accordance with equation (8) above. In equation (8), x is indicative of a value predetermined on the basis of required performance and so on.

In step S2, by use of values of x, T, k, and r, values of other configurational parameters s, l, and a are computed. The value of T is also a value predetermined by required performance and so on.

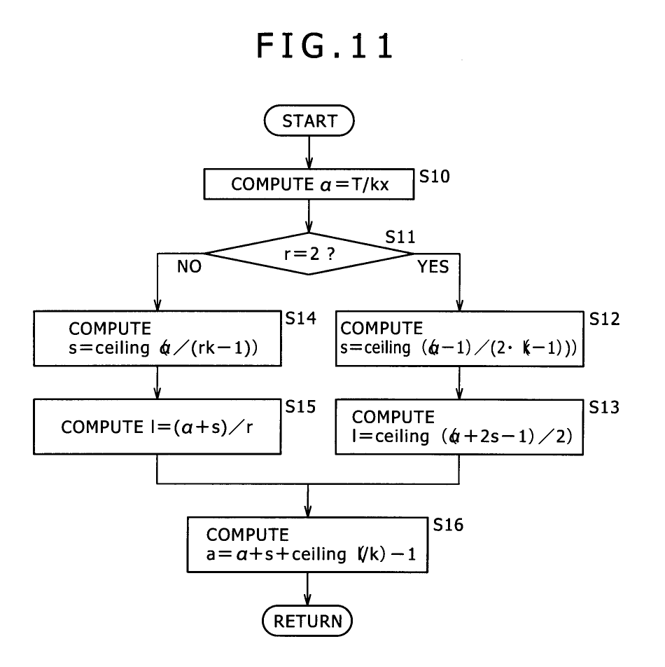

The following describes a procedure of computing values of s, l, and a that is executed in step S2 shown in FIG. 10 with reference to the flowchart shown in FIG. 11. For the convenience of description, details of step S2 will be described before details of step S0.

In step S10, a value of a is computed in accordance with equation (7) above.

In step S11, whether r=2 is determined.

If r=2 is determined in step S11, then, in step S12, a value of s is computed in accordance with equation (10) above.

Further, in step S13, a value of 1 is computed in accordance with equation (11) above.

If r=1/t not 2 is determined in step S11, then, in step S14, a value of S is computed in accordance with equation (10) above.

Also, in step S15, a value of l is computed in accordance with equation (11) above.

After the computation of s and l, a value of a is computed in accordance with equation (12) above in step S16. Then, the procedure returns to step S2 shown in FIG. 10 to end the parameter decision procedure.

The following describes a specific example of computation results with N=64, T=114, and x=2.

It is assumed here that k=3 and r=2 be predetermined in step S0. In step S1 shown in FIG. 10, m=2·3·2=12 was obtained.

In this case, in S10 shown in FIG. 11, α=114/(3·2)=19 is computed. Here, because r=2, after the decision of step S11, s=ceiling ((19−1)/(2·(3−1))=5 is computed in step S12.

In step S13, l=ceiling((19+2·5−1)/2)=14 is computed. In step S16, a=19+5+ceiling(14/3)−1=28 is computed.

The computation results of configurational parameters obtained as N=64, T=114, x=2, k=3, and r=2 are listed in a column second to the leftmost column of Table 3. The computations of the configurational parameters shown in the third, fourth, and fifth columns from the left will be sequentially described later.

TABLE 3

| Configurational | If k = 3, | | If k = 4, | If k = 8, |
|---|---|---|---|---|
| parameter | r = 2 | If k = 8, r = 1 | r = 1 | r = ½, u = 1 |
| T | 114 | 112 | 112 | 112 |
| m | 12 | 16 | 8 | 8 |
| s | 5 | 1 | 5 | 1 |
| l | 14 | 8 | 19 | 16 |
| a | 28 | 8 | 23 | 9 |
| p | 1 | 1 | 1 | 2 |
| M [bit] | 174N | 144N | 192N | 160N |
| | (≈1.55TN) | (≈1.29TN) | (≈1.71TN) | (≈1.43TN) |
| L | 86 | 72 | 95 | 80 |

The following describes a procedure of determining the values of k and r to be executed in step S0 shown in FIG. 10 with reference to the flowchart shown in FIG. 12.

It is desirable to determine the values of k and r so as to minimize memory size and latency and circuit scale. With the values of k and r of the survivor path processing unit 74, the values of k and r that minimizes memory size are not always the values of k and r that minimizes circuit scale. This is because the memory size of the survivor path processing unit 74 is a combination of the memory size of the path memory RAM 82 and the memory size of the shift register 81; therefore, in general, the circuit scale per bit of the shift register configured by a flip-flop is larger than the circuit scale per bit of the RAM.

Also, if r=2, it is required to use a dual-port RAM as the path memory RAM 82. If p=1 and r≦1 and s=1, the configuration can be obtained by use of a single-port RAM. As described above, if r=2, this requires to read path select information for two addresses in one clock, thereby requiring a RAM having two read ports. On the other hand, if r≦1 and s=1, the traceback circuit 83 may only read path select information by use of one port. And, there occurs no writing of new path select information while executing reading.

Generally, if the depth of RAM is small, the circuit scale of a dual-port RAM is about 20% greater than that of a single-port RAM (refer to Non-Patent Document 4). Even if the memory size of the path memory RAM 82 is about 20% greater than that of a dual-port RAM and can be realized with a single-port RAM, the circuit scale of that path memory RAM 82 is substantially the same as that of the realization with a dual-port RAM.

Therefore, in the selection of k and r values, not only memory size and latency but also circuit scale are considered. To be more specific, the values of k and r are determined that minimize circuit scale B₁ that is a combination of circuit scale y_{RAM} of the path memory RAM 82 and circuit scale y_{REG}·k×N of the shift register 81 that are expressed by equation (15) below.

B₁=y_{RAM}+y_{REG}·k×N (15)

Here, y_{RAM} is defined by type of RAM, bit width of RAM, and depth thereof. The types of RAM include a single-port RAM, a dual-port RAM of 1-write port 1-read port, and a dual-port RAM of 2-write port 2-read port, for example. In addition, y_{REG} is indicative of a circuit scale per bit and defined by a cell library used.

In step S20, maximum value kₘₐₓ and minimum value rₘᵢₙ of k that is a target of search are set. It should be noted that kₘₐₓ and rₘᵢₙ are supposed to satisfy a relation of kₘₐₓ>1/rₘᵢₙ. Also, y_{REG} is set.

In step S21, k and r are initialized to 2 each.

In step S22, traceback length T is computed in accordance with equation (16) below.

$$T = ceiling ( \frac{{T}_{init}}{kx} ) \cdot kx \qquad ( 16 )$$

In equation (16) above, Tᵢₙᵢₜ is an initial value of traceback length. If Tᵢₙᵢₜ can be divided by kx when the value of k is changed, this Tᵢₙᵢₜ is used as traceback length T of the survivor path processing unit 74; otherwise, a minimum integer exceeding Tᵢₙᵢₜ and divisible by kx is used as T.

In step S23, values of configurational parameters s, l, and a are computed in according with the procedure described above with reference to FIG. 11.

In step 24, type of RAM and y_{RAM} are defined from the current value of r, the values of configurational parameters s and a computed in step S23, and the value of k×N.

To be more specific, for the type of RAM, a single-port RAM is defined if p=1 and r≦1, and s=1. Also, if r=2 or p=2, a dual-port RAM having two read ports is defined. In other cases, a dual-port RAM having one read port is defined. Further, circuit scale y_{RAM} with bit width k×N and depth a in the RAM of the determined type is determined by data sheet and compilation.

Here, if a RAM of depth a cannot be realized because the depth is too small, the circuit scale of a RAM having a realizable maximum depth is used as y_{RAM}. If the RAM of bit width k×N cannot be realized because the width is too large, k×N bits are divided to be stored in two or more RAMs, a total of the circuit scales of these RAMs being y_{RAM}.

In step S25, circuit scale B₁ is computed in accordance with equation (15) above, a computation results being stored.

In step S26, it is determined whether the current value of k is equal to or higher than kₘₐₓ.

If the current value k is found to be not equal to or higher than kₘₐₓ in step S26, then, the value of k is incremented by one in step S27, subsequently repeating the processing of step S22 and on.

On the other hand, if the current value of k is found to be equal to or higher than kₘₐₓ in step S26, then it is determined in step S28 whether the current value of r is equal to or below rₘᵢₙ.

If the current value of r is determined to be not equal to or below rₘᵢₙ in step S28, then it is determined in step S29 whether the current value of r is 2 or not.

If the current value of r is determined to be 2 in step S29, then 1 is set to the value of t in step S30.

In step S31, 1 is set to the value of r.

In step S32, (t+1) is set to the value of k and then the above-mentioned processing of step S22 and on is repeated.

On the other hand, if the current value of r is found not to be 2 in step S29, then the value of t is incremented by one in step S33.

In step S34, it is determined whether the current value of t is a divisor of kx.

If the current value of t is found not to be a divisor of kx in step S34, then the procedure returns to step S33 to repeat the processing of incrementing the value of t by one.

If the current value of t is found to be a divisor of kx in step S34, then 1/t is set to the value of r in step S35 and then the above-mentioned processing of step S32 and on is executed.

On the other hand, if the current value of r is found to be equal to or below rₘᵢₙ in step S28, then values of k and r that minimize B₁ in B₁ stored so far are selected in step S36.

In step S37, traceback length T is computed in accordance with equation (16). Then, the procedure returns to step S0 shown in FIG. 10 to execute the above-mentioned processing of step S0 and on.

The following describes a specific computation with N=64, Tᵢₙᵢₜ=112, and x=2.

In step S20, kₘₐₓ, rₘᵢₙ and y_{REG} are set. Here, kₘₐₓ=10, rₘᵢₙ=½, and y_{REG}=10 are set.

In step S21, 2 is set to the values of k and r and the value of T is computed in step S22. Then, in step S23, values of configurational parameters s, l, and a are computed. In this case, s=14, l=28, and a=55 are computed.

In step S24, the type of RAM and y_{RAM} are obtained from a result of the above-mentioned computation. Here, for the simplicity of description, it is assumed that the circuit scale per bit of the RAM be constant without dependent on bit width k×N and depth a and y_{RAM} depend on only memory size akxN.

If type of RAM is single-port RAM, namely, p=1 and r≦1 and s=1, then y_{RAM}=2 ak×N. In the case of dual-port RAM, y_{RAM}=2.4 ak×N. Also, a RAM of comparatively small depth is assumed. Consequently, since the current value of r is r=2, y_{RAM}=2.4 ak×N=2.4·55·2·2·64=33792.

In step S25, B₁=33792+10·2·2·64=36352 is computed and a result thereof is stored. In step S26, since the current value of k is k=2 and smaller than kₘₐₓ=10, the procedure goes to step S27, in which k=3 is set, upon which the procedure returns to step S22.

The processing of step S22 through step S27 is repeated. If k=10, then, it is determined that the current value of k is equal to or higher than kₘₐₓ=10, upon which procedure goes to step S28.

In step S28, the current value of r is r=2 and higher than rₘᵢₙ=½, so that the procedure goes to step S29. Then, the above-mentioned processing of step S29 through step S32 is repeated until the current value of r is ½ and equal to or lower than rₘᵢₙ=½ are determined in step S28.

In step S36, k=8 and r=1 are selected as values for minimizing the value of B₁. In step S37, T=112 is computed.

The values of B₁ computed by use of the above-mentioned specific values and stored in step S25 are as listed in Table 4. An arrow shown over the numbers of computation result shown in Table 4 is indicative of a sequence that is obtained by computation. If k=8 and r=1, 26624 is obtained as the value of B₁.

TABLE 4

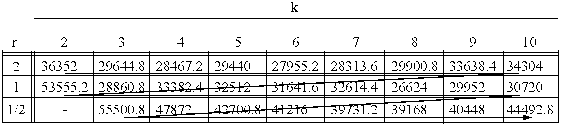

A computation result of each configurational parameter obtained by the procedure shown in FIG. 10 with N=64, T=112, x=2, k=8, and r=1 is shown in the third column from the left in Table 3.

As described above, the values of k and r are computed by considering not only memory size and latency but also circuit scale, thereby determining other configurational parameters.

Consequently, a memory size and a latency that are equal to or lower than those of related-art algorithms can be realized. In addition, because the path memory RAM 82 is used without dividing, no selector for selecting read information is required to simplify the control of reading, thereby minimizing the circuit scale of peripheral circuits. Further, the consideration of the type of path memory RAM also allows the reduction in circuit scale.

### Details of the Configuration of the Survivor Path Processing Unit

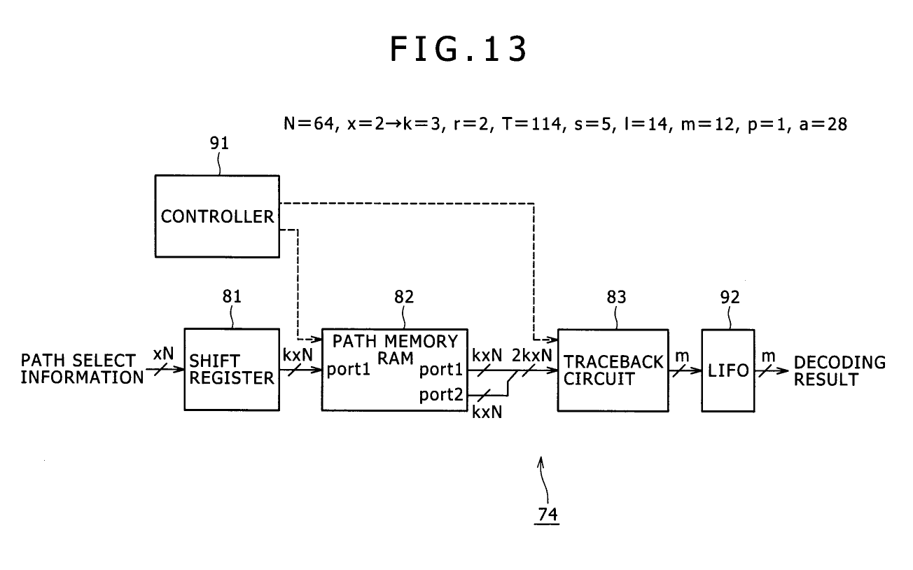

Referring to FIG. 13, there is shown a block diagram illustrating an exemplary configuration of the survivor path processing unit 74.

Referring to FIG. 13, there is shown a configuration of the survivor path processing unit 74 specified by the configurational parameters listed in the second column from the left in Table 3 obtained when k=3 and r=2. With reference to FIG. 13, parts of the configuration similar to those previous described with reference to FIG. 6 are denoted by the same reference numerals. Duplicate description will be skipped. As described above, if N=64 and x=2, the values of other configurational parameters are T=114, s=5, l=14, m=12, p=1, and a=28.

Since p=1, one traceback circuit 83 is arranged for a circuit that executes traceback processing.

A controller 91 controls the writing of path select information to a path memory RAM 82 and the reading of path select information from the path memory RAM 82.

A LIFO (Last-in First-out) 92 stores data supplied from a traceback circuit 83 and reads the data on a last-in first-out basis, outputting the read data as a decoding result.

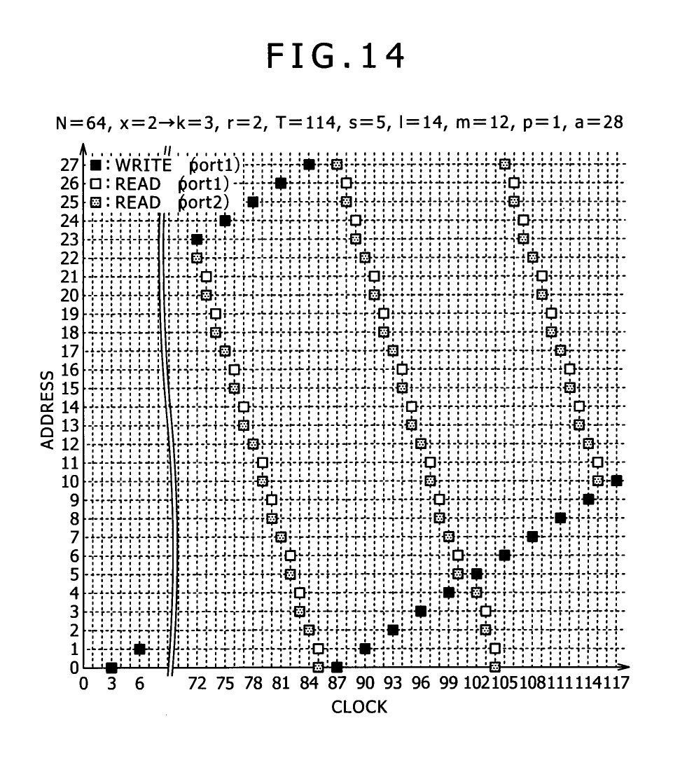

Referring to FIG. 14, a memory access chart indicative of timings of the writing of path select information to the path memory RAM 82 shown in FIG. 13 and the reading of path select information from the path memory RAM 82. Under the control by the controller 91, operations as shown in FIG. 14 are realized.

The horizontal axis shown in FIG. 14 is indicative of clock and the vertical axis is indicative of addresses of the path memory RAM 82. One black square is indicative of a timing of writing path select information to be executed by use of port 1 and an address to which path select information is written. One white square is indicative of a timing of reading path select information by use of port 1 and an address from which path select information is read. One shadowed square is indicative of a timing of reading path select information to be executed by use of port 2 and an address from which path select information is read. This holds the same with a memory access chart to be described later.

Since k=3, path select information of xN=2·64=128 bits entered every clock is accumulated in the shift register 81 for three inputs and the information for three inputs is collectively outputted.

As shown in FIG. 14, writing of path select information to one address is executed every three clocks, by use of port 1. The bit width of the path select information written by one write operation is k×N=3·2·64=384 bits.

In the example shown in FIG. 14, path select information is written at address 0 with a timing of the third clock and at address 1 with a timing of the sixth clock.

With a timing of 72nd clock at which path select information for (T+skx)=114+5·3·2=144 time was stored in the path memory RAM 82, the reading of path select information from the path memory RAM 82 is started. After the starting of reading, the writing of path select information to the path memory RAM 82 is also continued.

Since r=2, reading of path select information is executed by accessing two addresses every clock. In this case, the path select information that is a double kx=3·2=6 time, namely, the path select information of 2k×N=768 bits that is information for 2 kx=12 time, is read every clock and entered in the traceback circuit 83 that traces back paths for m=12 time in one clock. In the traceback circuit 83, traceback processing for (T+skx)=144 time is executed by taking a time for l=14 clocks.

However, with a timing when writing is executed by use of one port, the reading of path select information can be executed only by use of the other port. In this case, only the path select information read from one address is entered in the traceback circuit 83. In the traceback circuit 83, traceback processing is executed by tracing back paths for m/2=6 time in one clock.

In the example shown in FIG. 14, writing of path select information to address 23 is executed by use of port 1 with a timing of the 72nd clock and, at the same time, reading of path select information from address 22 is executed by use of port 2. In addition, with a timing of the 73rd clock at which path select information is not written, reading of path select information from address 21 is executed by use of port 1 and reading of path select information from address 20 is executed by use of port 2. The read path select information is sequentially used for the traceback circuit 83 to trace back the path.

The reading of the path select information stored up to the timing of the 72nd clock is continued up to a timing of the 85th clock. Then, the writing and reading of path select information are repeated.

Of m=12 bits that is an output from the traceback circuit 83 every clock, an output of the path select information for the last s=5 addresses is entered in the LIFO 92. Every time one traceback operation is executed, skx=30 bits are outputted as a decoding result.

Here, the path memory RAM 82 is a dual-port RAM having two read ports and executes a write-first operation in which the information written immediately before is outputted from the read port by which the writing has been executed.

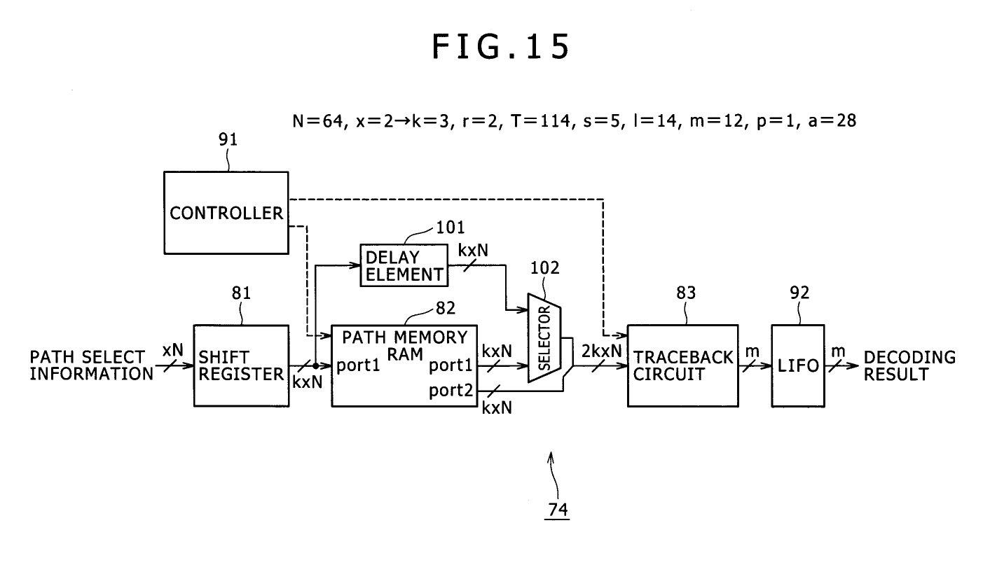

Referring to FIG. 15, there is shown a block diagram illustrating another exemplary configuration of the survivor path processing unit 74.

Configurational parameters for use in realizing the configuration shown in FIG. 15 are substantially the same as those for use in realizing the configuration shown in FIG. 13. With reference to FIG. 15, parts of the configuration similar to those previously described with reference to FIG. 13 are denoted by the same reference numerals.

For example, if a RAM for executing a write-first operation, such as the path memory RAM 82 shown in FIG. 13, is not used, a survivor path processing unit 74 is configured by a delay element 101 and a selector 102 in addition to the same configuration as that shown in FIG. 13 as shown in FIG. 15.

The delay element 101 delays an output of a shift register 81 by the same time as that required for reading path select information from the path memory RAM 82, outputting the delayed path select information to the selector 102.

The selector 102 selects either an output of the delay element 101 or path select information read from the path memory RAM 82 by use of port 1 and outputs the selected output or information to the traceback circuit 83. The selector 102 selects an output of the delay element 101 with a timing at which the path select information at the address 22 to be read when traceback processing is started is outputted from the path memory RAM 82, as with the 72nd clock shown in FIG. 14 for example; with other timings, the selector 102 selects the path select information read from the path memory RAM 82. The path select information read from the port 2 of the path memory RAM 82 is directly supplied to the traceback circuit 83.

Consequently, the same information as that supplied by a write-first operation can be supplied to the traceback circuit 83. In the path memory RAM 82 shown in FIG. 15, path select information is written and read also with the same timing as indicated in FIG. 14.

If a delay by the delay element 101 is a time equivalent to one clock, a delay element for k×N bits is not required for generating the same output as that obtained by delaying write information by a time equivalent to one clock. For example, it is practicable to generate the same output as that obtained by delaying write information by a time equivalent to one clock by adding one more stage of the number of registers configuring the shift register 81 to (k+1) stages.

In the configuration of the survivor path processing unit 74 at this moment, registers for xN bits may only be added to the shift register 81, other parts of the configuration being substantially the same as those shown in FIG. 13.

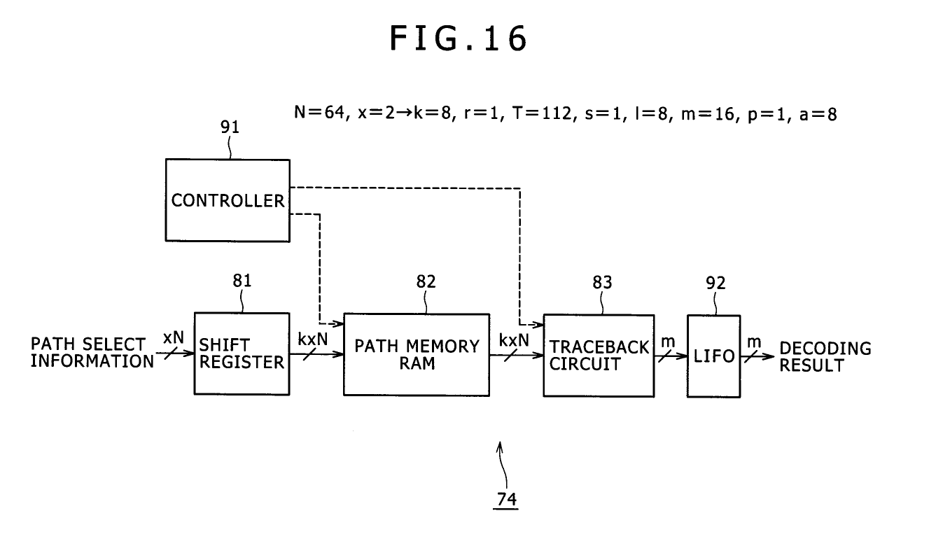

Referring to FIG. 16, there is shown a block diagram illustrating still another exemplary configuration of the survivor path processing unit 74.

FIG. 16 shows a configuration of a survivor path processing unit 74 specified by the configurational parameters listed in the third column from the left in Table 3 obtained when k=8 and r=1. As described above, if N=64 and x=2, values of other configurational parameters are T=112, s=1, l=8, m=16, p=1, and a=8.

This still another configuration is substantially the same as the configuration shown in FIG. 13 except that the values of configurational parameter are different and the number of ports of the path memory RAM 82 is different.

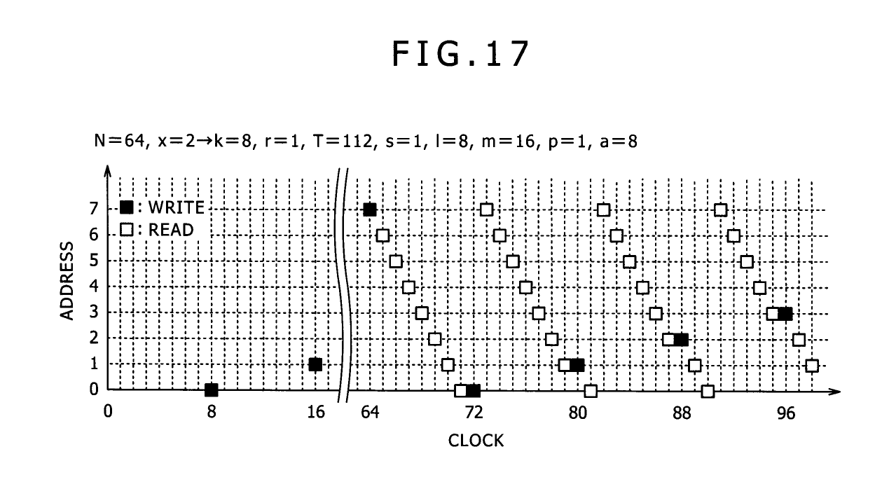

Referring to FIG. 17 there is shown a memory access chart indicative of timings of writing path select information to a path memory RAM 82 shown in FIG. 16 and reading path select information from the path memory RAM 82.

Since k=8, path select information of xN=2·64=128 entered every clock in a shift register 81 is accumulated for eight inputs and information for eight inputs is collectively outputted.

As shown in FIG. 17, the writing of path select information to one address is executed every eight clocks. The bit width of the path select information written by one write operation is k×N=8·2·64=1024 bits.

In the example shown in FIG. 17, writing is executed to address 0 with a timing of the 8th clock and writing is executed to address 1 with a timing of 16th clock.

Reading of path select information starts with a timing of 65th clock that is a timing next to the timing of 64th clock at which the path select information for (T+skx)=112+1·8·2=128 time was stored in the path memory RAM 82.

Since r=1, path select information is read by accessing to one of different addresses every clock. In this case, the path select information of k×N=1024 bits that is information for kx=16 time is read to be entered in the traceback circuit 83 in which paths for m=16 time is traced back in one clock. In the traceback circuit 83, traceback processing for (T+skx)=128 is executed for a time equivalent to 1=8 clocks.

In the example shown in FIG. 17, reading is executed from address 6 with a timing of 65th clock and reading is executed from address 5 with a timing of 66th clock. The read path select information is sequentially used for tracing back paths by the traceback circuit 83.

The reading of the path select information stored until a timing of the 64th clock is continued up to a timing of the 71st clock and then the writing and reading of path selection information are repeated likewise.

Of m=16 bits that is an output from the traceback circuit 83 every clock, an output for the path select information for the last s=1 address is entered in the LIFO 92 and, every time one traceback processing operation is executed, skx=16 bits are outputted as a decoding result.

The path memory RAM 82 shown in FIG. 16 is a single-port RAM because p=1 and r≧1 and s=1 as shown in the third column from the left in Table 3. This single-port RAM executes a write-first operation.

### <Variation 1>

Generally, the layout position of the path memory RAM 82 in a chip is determined beforehand. In order to prevent the degree of freedom in the module layout involved in wiring delay from reducing, information read from the RAM is once held in flip-flop before use in the traceback circuit 83.

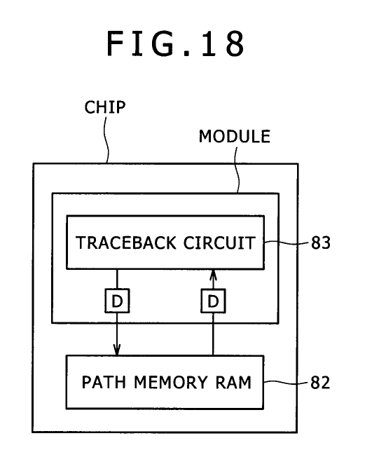

Referring to FIG. 18, there is shown an exemplary layout of the path memory RAM 82 in a chip.

As shown in FIG. 18, a module including the traceback circuit 83 and the path memory RAM 82 are arranged on a same chip. In FIG. 18, there are shown only the traceback circuit 83 and the path memory RAM 82; however, another configuration of the reception apparatus 51 is also appropriately arranged in a same module as the traceback circuit 83 or in a different module. This another module of the reception apparatus 51 may be arranged on a chip that is different from the chip on which the traceback circuit 83 is arranged.

A flip-flop (a block indicated by character “D”) is arranged in the module including the traceback circuit 83 between the traceback circuit 83 and the path memory RAM 82 as shown in FIG. 18. For example, data read from the path memory RAM 82 is once held in this flip-flop to be supplied to the traceback circuit 83 for trace-back processing.

It is also practicable to determine the values of k and r in a same procedure as that described before with reference to the flowchart shown in FIG. 12 by considering a circuit scale of this flip-flop.

In this case, a value of the number of read ports z of the path memory RAM 82 expressed by equation (17) below is used. In addition, B₂ indicative of a circuit scale with the circuit scale of this flip-flop considered is computed to determine values of k and r that minimize B₂. B₂ is expressed by equation (18) below.

$$\begin{matrix}z = \{ \begin{matrix}1 , & if p = 1 and r ≦ 1 \\ 2 , & else\end{matrix} & ( 17 ) \\ {B}_{2} = {y}_{RAM} + {y}_{REG} \cdot ( 1 + z ) \cdot kxN & ( 18 )\end{matrix}$$

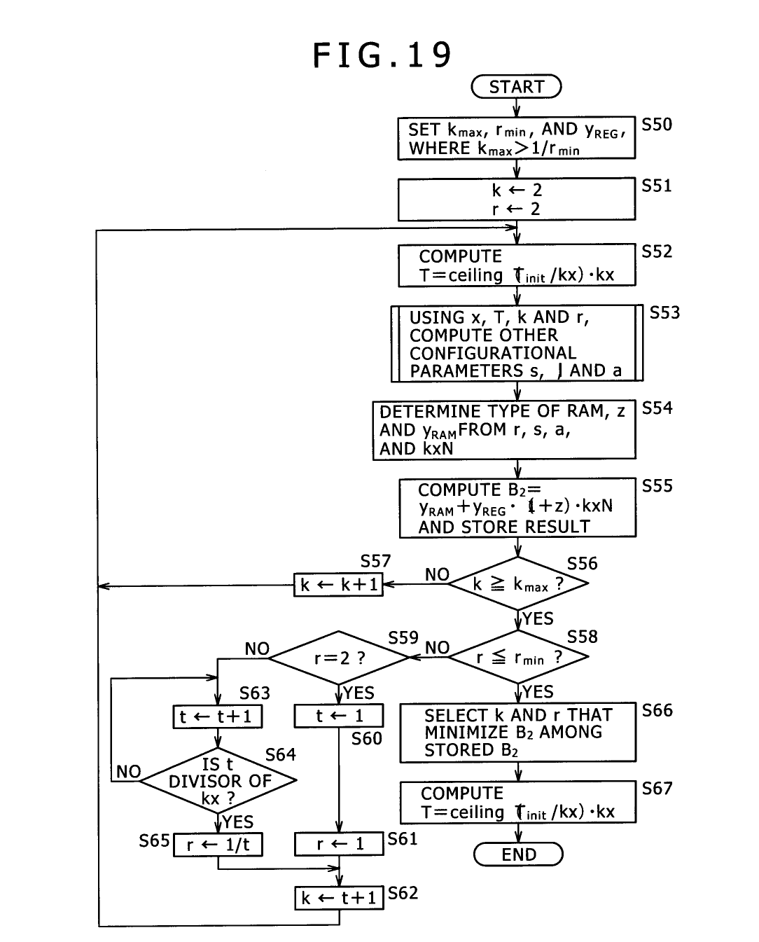

The following describes an exemplary variation to the procedure of determining k and r to be executed in step S0 shown in FIG. 10 with reference to the flowchart shown in FIG. 19.

The processing of steps S50 through S53 and S56 through S65 and S67 shown in FIG. 19 is substantially the same as that of steps S20 through S23, S26 through S35 and S37 shown in FIG. 12, so that the duplicate description will be skipped as appropriate.

In step S50, kₘₐₓ, rₘᵢₙ, and y_{REG} are set. In step S51, 2 is set to k and r respectively.

In step S52, traceback length T is computed. In step S53, values of configurational parameters s, l, and a are computed.

In step S54, a type of RAM and yp_{RAM} are determined from the current value of r and the values of configurational parameters s and a computed in step S53, and a value of k×N. In addition, the number of read ports z is determined in accordance with equation (17) above.

If the determined type of RAM is a single-port RAM or a dual-port RAM having one read port, z=1; if the type of RAM is a dual-port RAM having two read ports, z=2.

In step S55, circuit scale B₂ is computed in accordance with equation (18) and a computation result is stored.

If the current value of k is determined to be equal to or higher than kₘₐₓ in step S56 and the current value of r is determined to be equal to or lower than rₘᵢₙ in step S58, then the procedure goes to step S66.

In step S66, values of k and r that minimize the value of B₂ stored so far are selected.

In step S67, traceback length T is computed and then the processing of step S0 and on shown in FIG. 10 is executed.

Like the above-mentioned example, if N=64, Tᵢₙᵢₜ=112, and x=2, then k=8, r=1, and T=112 are computed by following the procedure shown in FIG. 19. The computation results of the configurational parameters obtained by following the procedure shown in FIG. 10 are the same as those listed in the third column from the left in Table 3.

### <Variation 2>

It is necessary for the traceback circuit 83 to execute N-to-1 select processing of m/x stages in one clock. The N-to-1 select processing selects one state (path) from among N states. Details of the execution of the N-to-1 selection processing of m/x stages in one clock will be described later.

Let a clock frequency to be used as a clock frequency that provides a reference of operation timings in the survivor path processing unit 74 be f_{c}, then a problem occurs if an operation at this clock frequency f_{c} is impossible. An operation at clock frequency f_{c} may become impossible if a delay of the traceback processing is large that must be completed within one clock because m is large, for example.

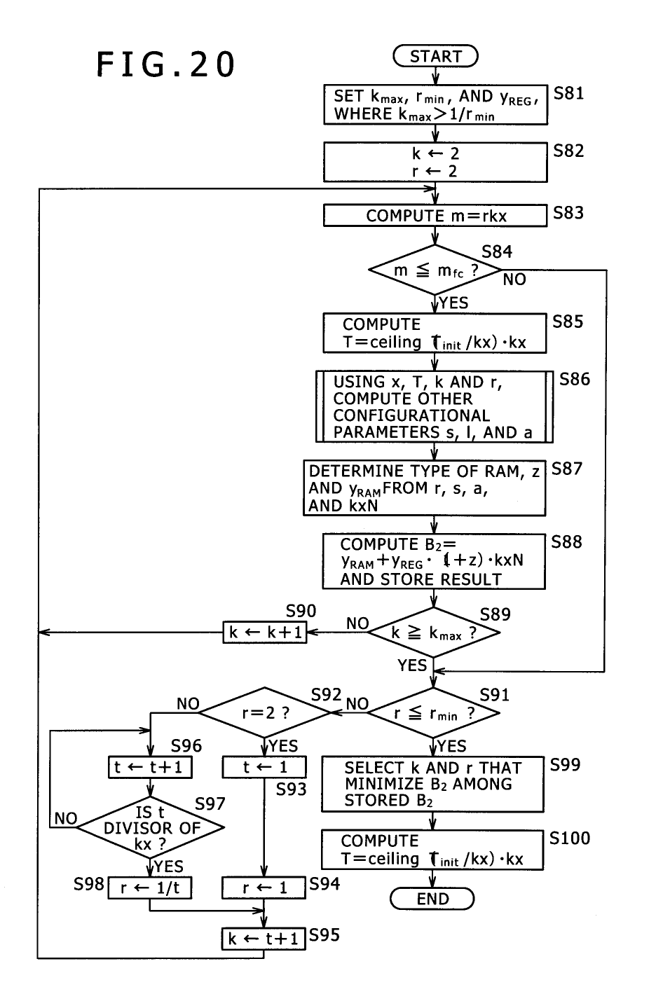

In order to solve this problem, the value of m indicative of the number of paths (time) to be traced back may be made small as to make an operation possible at clock frequency f_{c}. In order to make the value of m small, the value of k or r may be made small in accordance with equation (8) above. The value of m for enabling the operation at clock frequency f_{c} can be obtained by determining the values of k and r by following the procedure shown in FIG. 20 with the maximum value of m enabling the operation at clock frequency f_{c} being m_{fc}.

The following describes another exemplary variation of the procedure for determining k and r to be executed in step S0 shown in FIG. 10 with reference to the flowchart shown in FIG. 20.

The processing shown in FIG. 20 is substantially the same as the processing described above with reference to FIG. 19 except that the processing of steps S83 and S84 is added. The duplicate description will be skipped appropriately.

In step S81, kₘₐₓ, rₘᵢₙ, and y_{REG} are set. In step S82, 2 is set to k and r respectively.

In step S83, a value of m is computed in accordance with equation (8) above. In step S84, it is determined whether the value of m is equal to or lower than m_{fc}.

If the value of m is found to be equal to or lower than m_{fc} in step S84, traceback length T is computed in step S85. In step S86, configurational parameters s, l, and a are computed.

In step S87, a type of RAM and y_{RAM} are determined from the current value of r, the values of configurational parameters s and a computed in step S86, and the value of k×N. In addition, the number of read ports z is determined in accordance with equation (17) above.

In step S88, circuit scale B₂ is computed in accordance with equation (18) above and a computation result is stored.

On the other hand, if the value of m is found not equal to or lower than m_{fc} in step S84, step S85 through S89 are skipped.

If the value of k is found to be equal to or higher than kₘₐₓ in step S89 and the value of r is found to be equal to or lower than rₘᵢₙ in step S91, then the procedure goes to step S99.

In step S99, the values of k and r that minimize B₂ stored so far are selected.

In step S100, traceback length T is computed. Then, the processing of S0 and on shown in FIG. 10 is executed.

As described above, if N=64, Tᵢₙᵢₜ=112, and x=2 and m_{fc}=8, then k=4, r=1, and T=112 are computed by following the procedure shown in FIG. 20. Computation results of the configurational parameters obtained by following the procedure shown in FIG. 10 in this case are listed in the fourth column from the left in Table 3.

It should be noted that, with reference to FIG. 20, an example was described in which configurational parameters are computed by considering the circuit scale of the flip-flop for holding the data read from the path memory RAM 82; however, it is also practicable to compute the configurational parameters by adding the processing of steps S83 and S84 without considering this circuit scale.

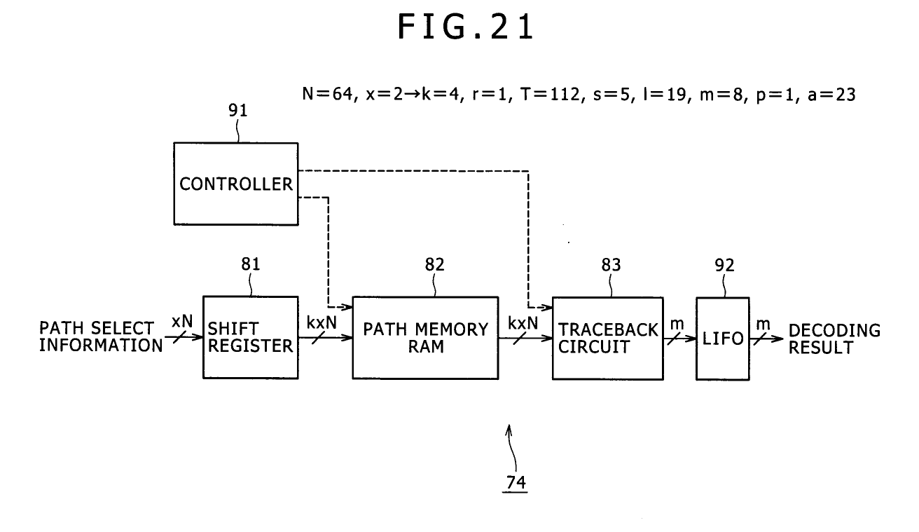

Referring to FIG. 21, there is shown a block diagram illustrating an exemplary configuration of the survivor path processing unit 74.

FIG. 21 shows a configuration of the survivor path processing unit 74 specified by the configurational parameters listed in the fourth column from the left in Table 3 obtained when k=4 and r=1. As described above, if N=64 and x=2, then the values of other configurational parameters are T=112, s=5, l=19, m=8, p=1, and a=23. Although the values of configurational parameters are different, the configuration itself is substantially the same as that shown in FIG. 16.

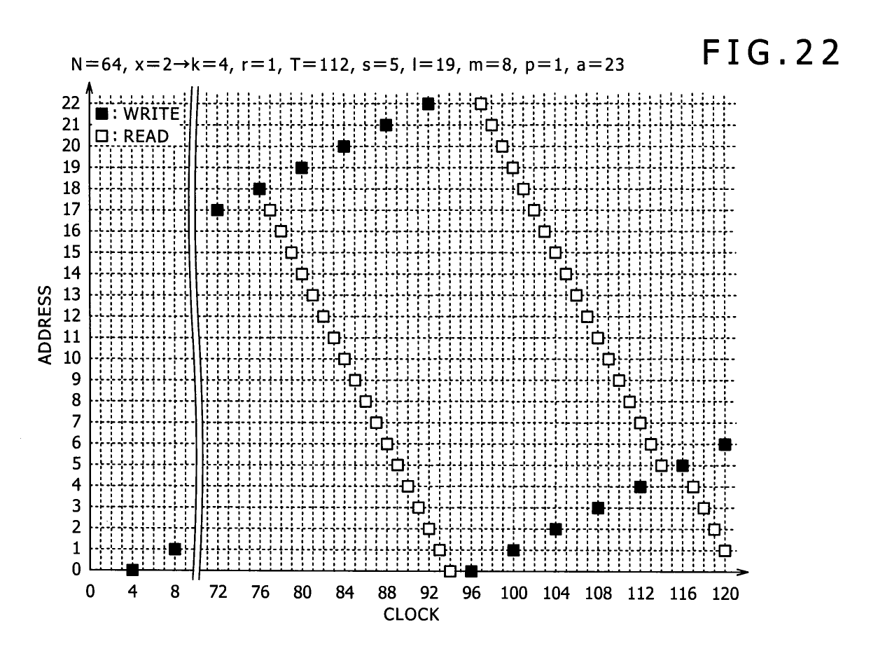

FIG. 22 shows a memory access chart indicative of timings of writing path select information to the path memory RAM 82 and reading path select information from the path memory RAM 82 shown in FIG. 21.

Since k=4, the path select information of xN=2·64=128 bits entered every clock is accumulated for four inputs in the shift register 81 and information for four inputs is collectively outputted.

As shown in FIG. 22, writing of path select information to one address is executed every four clocks. The bit width of the path select information to be written in one write operation is k×N=4·2·64=512 bits.

In the example shown in FIG. 22, writing to address 0 is executed with a timing of the fourth clock and writing to address 1 is executed with a timing of the eighth clock.

Reading of path select information is started with a timing of 77th clock next to a timing of the 76th clock with which path select information for T+skx=112+5·4·2=152 time is stored in the path memory RAM 82.

Since r=1, reading of path select information is executed by accessing different one address every clock. In this case, the path select information of k×N=512 bits that is information for kx=8 time is read every clock and is entered in the traceback circuit 83 that traces back paths for m=8 time in one clock. In the traceback circuit 83, traceback processing for T+skx=152 time is executed by taking a time for l=19 clocks.

In the example shown in FIG. 22, reading from address 17 is executed with a timing of 77th clock and reading from address 16 is executed with a timing of the 78th clock. The read path select information is sequentially used for the traceback circuit 83 to trace back paths.

The reading of the path select information stored up to a timing of the 76th clock is continued up to a timing of the 94th clock. Then, the writing and reading of path select information are repeated likewise.

Of m=8 bits that is the output from the traceback circuit 83 every clock, an output for the path select information for the last s=5 addresses is entered in the LIFO 92 and, every time one traceback processing operation is executed, skx=40 bits are outputted as a decoding result.

The path memory RAM 82 shown in FIG. 21 is a dual-port RAM of 1-write port 1-read port because p=1 and r≧1 and s=5 as listed in the fourth column from the left in Table 3.

Now, the following describes details of the execution of N-to-1 select processing of m/x stages in the traceback circuit 83.

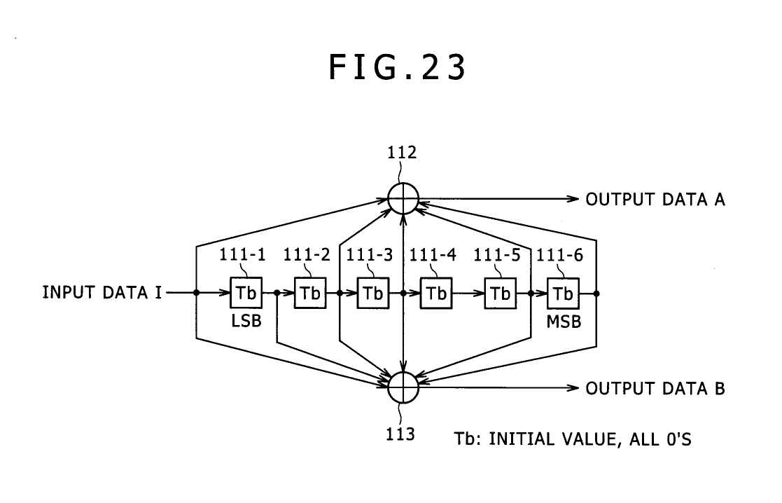

Generally, each input in a Viterbi decoder is encoded by a convolutional encoder as shown in FIG. 23.

In the example shown in FIG. 23, a shift register is configured by registers 111-1 through 111-6 and data of one bit is sequentially held by each of these registers as input data I.

Input data I, a value of the register 111-2, a value of the register 111-3, a value of the register 111-5, and a value of the register 111-6 are entered in an adder 112 and a result of exclusive OR operation is outputted as convolutionally encoded output data A. In addition, input data I, a value of the register 111-1, a value of the register 111-2, a value of the register 111-3, a value of the register 111-5, and a value of the register 111-6 are entered in an adder 113 and a result of an exclusive OR operation is outputted as convolutionally encoded output data B. A convolutional encoder shown in FIG. 23 is a circuit of coding ratio 1/2.

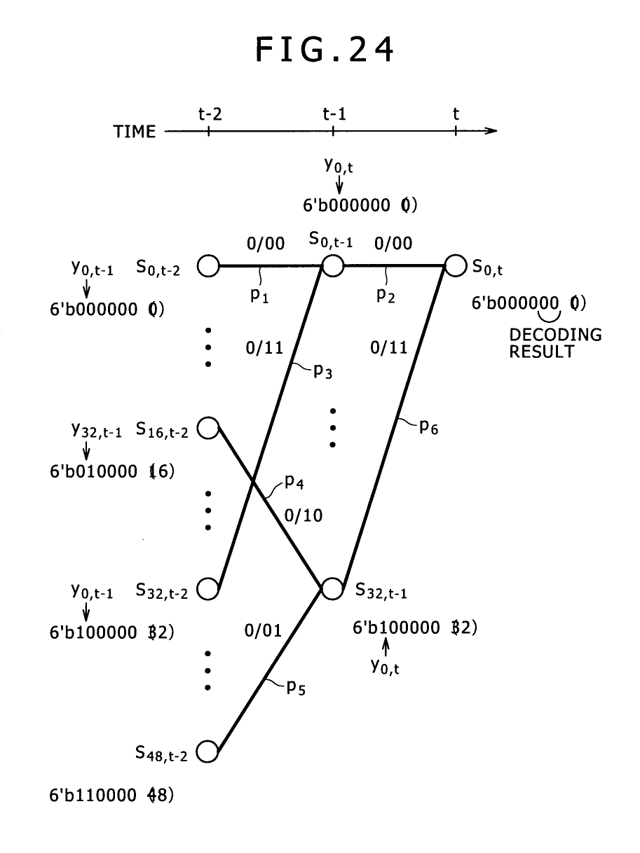

A sequence encoded by the convolutional encoder shown in FIG. 23 can be represented by a trellis diagram shown in FIG. 24.

Referring to FIG. 24, S_{n,t} denotes state n at time t. FIG. 24 shows, in a trellis diagram, paths for two time in which S_{0,t} is provided at time t with a total number of states being 64 for example. The states correspond to the values of the registers of six bits shown in FIG. 23, the initial state being state 0.

In the example shown in FIG. 24, a number and a slash (/) shown near each path denote a relation between input and output in the convolutional encoder shown in FIG. 23. For example, with path p₄, if value 0 is entered as input data I, 1 is outputted as a value of output data A and value 0 is outputted as a value of output data B.

For example, if input data I is 0 when state is 0 at time (t−2), namely, S_{0,t-2}, then the value of each register shown in FIG. 23 remains 0 and the state at next time (t−1) is also 0, namely, S_{0,t-1}. Likewise, if input data I is 0 when state is 16 at time (t−2), namely, S_{16,t-2}, a value of each register shown in FIG. 23 is 100000 in binary notation and the state at next time (t−1) is 32, namely, S_{32,t-1}.

In the ACS processing unit, path metrics of two paths connected to each of 64 states S_{n,t} (0≦n≦63) are computed (Hamming distances between the states are added together) at each time. In addition, a path having the minimum path metric is selected as a survivor path and path select information of one bit y_{n,t} is outputted.

Then, this path select information is stored in the path memory to get a maximum likelihood code sequence (a decoding result) by tracing back the survivor path in a traceback circuit in a subsequent stage.

In the selection of a survivor path, a path can be selected from path p₁ from S_{0,t-2} and path p₃ from S_{32,t-2} connected to S_{0,t-1}, for example, shown in FIG. 24. If P₁ is selected, 0 is stored as path select information; if p₃ is selected, 1 is stored as path select information, thereby indicating which path was selected in executing traceback operation to trace back the previous state.

The shift register shown in FIG. 23 is configured such that input data I is entered at the LSB side thereof, so that path select information y_{n,t} shown in FIG. 24 matches the MSB of the state of the selected path.

For example, assume that, in the selection of the path of the state 32 at time (t−1), path p₄ be selected from a group of path p₄ from S_{16,t-2} and path p₅ from S_{48,t-2} connected to S_{32,t-1} and 0 be stored as path select information y_{32,t-1.}

Further, assume that, in the selection of a path of state 0 at next time t, path p₆ be selected from a group of path p₂ from S_{0,t-1} and path p₆ from S_{32,t-1} connected to S_{0,t} and 1 be stored as path select information y_{0,t}.

At this moment, when a traceback operation is started from state 0 at time t, namely, S_{0,t}, the traceback circuit first reads path select information y_{n,t} at time t from the path memory and selects the path select information of state 0, thereby getting y_{0,t}=1. Consequently, the immediately preceding state is found to be S_{32,t-1}.

Next, the traceback circuit reads path select information y_{n,t-1} at time (t−1) from the path memory to select the path select information of state 32, thereby getting y_{32,t-1}=0. Consequently, the state preceding the above-mentioned state is found to be S_{16,t-2}.

Thus, in the traceback processing, preceding states can be traced back one by one to get a maximum likelihood decoding result.

Here, in order to trace back states for one time, path select information in the state currently traced back must be selected from among path select information Y_{n,t} for 64 states read from the path memory as described above. In the above, since the number of states is N, N-to-1 select processing is required.

Further, as described above, in the traceback circuit 83, states for m times are traced back in one clock. Normally, N-to-1 selection processing of m stages may only be executed. If path select information of radix-2^{x} is entered, the path select information for x times is written to the path memory RAM 82 at a time, so that the number of stages of N-to-1 select processing is m/x.

### <Variation 3>

It is also practicable for traceback processing to be executed by taking a time equivalent to (s+u)·k clocks, where u is a positive integer satisfying u≦s.

In this case, traceback processing does not end within a time equivalent to sk clocks. Therefore, two or more traceback circuits may be arranged in parallel to which the ports of the path memory RAM 82 are respectively allocated, thereby making these traceback circuits execute traceback processing in parallel in time.

For example, for next traceback processing necessary for starting halfway the traceback processing reading path select information by use of port 1, the other traceback circuit is made read path select information by use of port 2 to execute the traceback processing.

At this moment, port 1 is required to read path select information for (T+skx) time and write path select information u times in (s+u)·k clocks. One write operation of u times of writing is the information that is first used in traceback processing to be started immediately after as described with reference to equation (9) above, so that this one write operation can share the writing and reading of path select information.

Therefore, r, s, and u must satisfy a relation shown in equation (19) below. Also, from equation (19), s is expressed by equation (20) below. In this example, s in equation (10) above is replaced by that in equation (20) to compute other configurational parameters.

$$\begin{matrix}( s + u ) \cdot k [ clock ] ≧ \frac{α + s}{r} + u - 1 and r ≦ 1 & ( 19 ) \\ s ≧ ceiling ( \frac{α - r \cdot \{ ( k - 1 ) \cdot u + 1 \}}{rk - 1} ) and k > \frac{1}{r} and r ≦ 1 & ( 20 )\end{matrix}$$

Further, the number of clocks l necessary for traceback processing expressed by equation (11) is replaced by that expressed by equation (21) below. Also, equation (20) is a condition for deriving the traceback processing started every sk clocks such that this traceback processing ends within (s+u)·k clocks, where u is a positive integer satisfying u≦s. Hence, in this example, the number of traceback circuits for tracing back paths for m time in one clock arranged in the survivor path processing unit is 2 (p=2).

$$l = \frac{α + s}{r} + u - 1 and r ≦ 1 \qquad ( 21 )$$

Configurational parameters obtained by obtaining a value m in step S1 shown in FIG. 10 and by executing the computation in step S2 with T=112, x=2, k=8, r=½, and u=1 are listed in the fifth column from the left in Table 3. In steps S14 and S15 shown in FIG. 11 indicative of the procedure of the computation to be executed in step S2, the computations of equation (20) and equation (21) are executed.

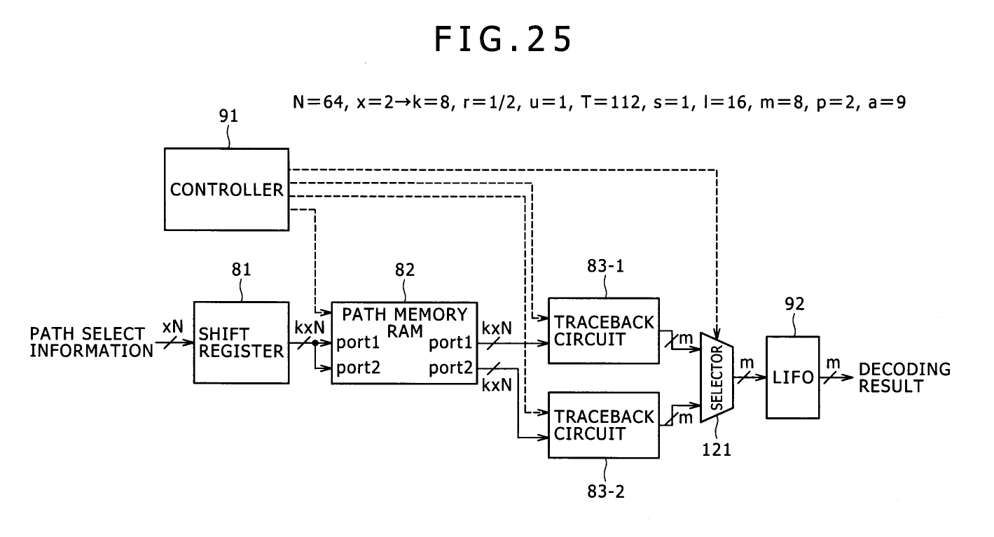

Referring to FIG. 25, there is shown a block diagram illustrating an exemplary configuration of the survivor path processing unit 74.

FIG. 25 shows a configuration of the survivor path processing unit 74 specified by the configurational parameters listed in the fifth column from the left in Table 3. As described above, if N=64 and x=2, the values of the configurational parameters are k=8, r=½, u=1, T=112, s=1, l=16, m=8, p=2, and a=9.

Since p=2, traceback circuits 83-1 and 83-2 are arranged as traceback circuits as shown in FIG. 25. The port 1 of the path memory RAM 82 is allocated as a port for the traceback circuit 83-1 and the port 2 is allocated as the port for the traceback circuit 83-2. In addition, behind the traceback circuits 83-1 and 83-2, a selector 121 is arranged. Other parts of configuration are substantially the same as those shown in FIG. 21, for example.

The traceback circuits 83-1 and 83-2 each execute traceback processing on the basis of the path select information read from the path memory RAM 82 and output a processing result to the selector 121.

The selector 121 selects one of the data supplied from the traceback circuit 83-1 and the data supplied from the traceback circuit 83-2 under the control of a controller 91 and outputs the selected data to a LIFO 92.

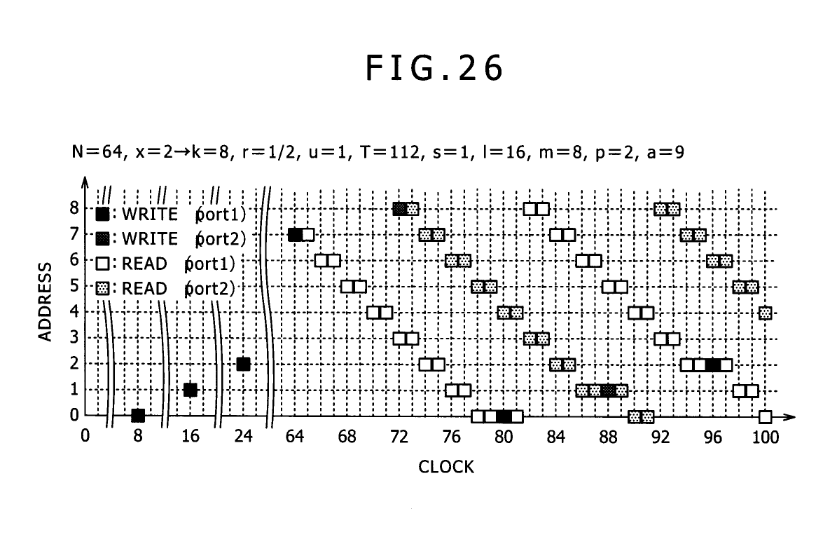

Referring to FIG. 26, there is shown a memory access chart indicative of timings of writing path select information to the path memory RAM 82 and reading path select information from the path memory RAM 82 shown in FIG. 25.

Since k=8, path select information of xN=2·64=128 bits entered each clock is accumulated in a shift register 81 for eight inputs and information for eight inputs is collectively outputted.

As shown in FIG. 26, the writing of path select information to one address is executed every eight clocks. The bit width of the path select information written in one write operation is k×N=8·2·64=1024 bits.

In the example shown in FIG. 26, writing is executed to address 0 with a timing of eighth clock and writing is executed to address 1 with a timing of 16th clock.

Reading of path select information is started with a timing of 65th clock that is a timing next to a timing of the 64th clock with which the path select information for (T+skx)=112+1·8·2=128 time is stored in the path memory RAM 82.

Since r=½, path select information is read by accessing different one address every two clocks. In this case, the path select information of k×N=1024 bits that is information for kx=16 time is read every two clocks.

The read path select information is entered in the traceback circuit 83-1 connected to the port 1 of a group of the traceback circuit 83-1 and the traceback circuit 83-2 that trace back paths for m=8 time in one clock. The traceback circuit 83-1 executes traceback processing for (T+skx)=128 time by taking a time equivalent to 1=16 clocks.

On the other hand, because the next traceback processing must be started every sk=8 clocks, the next traceback processing to be started halfway in the traceback processing being executed by use of the port 1 is executed by the traceback circuit 83-2 by use of the read port 2.

Of m=8 bits outputted from each traceback circuit, the output for the path select information for the last s=1 address is switched by the selector 121 every sk=8 clocks to be entered in a LIFO 92. From the LIFO 92, skx=16 bits are outputted as a decoding result every time one traceback processing operation is executed.

The path memory RAM 82 shown in FIG. 25 is a dual-port RAM of 2-write port, 2-read port.

### <Variation 4>

It is also practicable to change the shift registers of k stages for storing input signals for k inputs to pretraceback circuits of k stages. This enables the compatibility with operations at higher clock frequencies. To be more specific, in the above-mentioned examples, N-to-1 select processing of m/x stages must be executed in one clock. However, changing to the pretraceback circuits of k stages may only make the traceback circuit execute N-to-1 select processing of one stage in one clock.

For example, in the above-mentioned case of T=112, x=2, k=8, and r=1, the latency is substantially the same as the latency of the related-art pretraceback algorithm, but the memory size can be reduced by approximately 10%. For the related-art pretraceback algorithm to realize the memory sizes listed in Table 1, the path memory must be configured by a dual-port RAM. In contrast, changing the shift register to the pretraceback circuit in the configuration shown in FIG. 16 for example makes it practicable to configure the path memory by a single-port RAM, thereby realizing the path memory with a smaller circuit scale.

Further, this variation 4 allows the design of a survivor path processing unit in accordance with clock frequencies to be realized, thereby providing the compatibility with operations at high clock frequencies.

The present application contains subject matter related to that disclosed in Japanese Priority Patent Application JP 2009-050200 filed in the Japan Patent Office on Mar. 4, 2009, the entire content of which is hereby incorporated by reference.

It should be understood by those skilled in the art that various modifications, combinations, sub-combinations and alternations may occur depending on design requirements and other factors insofar as they are within the scope of the appended claims or the equivalent thereof.

What is claimed is:

1. A decoding apparatus comprising:
with N and x each being a positive integer and k being a positive integer being equal to or greater than 1,
a shift register of k stages configured to accumulate path select information for k inputs that is information about a survivor path of xN bits made up of radix-2^{x} in each transient state of a convolutional code of the number of states N;
a path memory having one bank configured to store, at one address, said path select information for k inputs accumulated in said shift register; and
a traceback circuit configured to trace back paths for m=rkx time in one clock by use of said path select information read from said path memory with t being a divisor of kx and r being 2 or 1/t.

2. The decoding apparatus according to claim 1, wherein:
a traceback length of said one traceback circuit is represented by positive integer T divisible by kx;
the number of clocks necessary for one traceback processing operation is represented by l in the case where next traceback processing is started every s times said path select information is written to said path memory;
α=T/(kx); and
ceiling (b) represents a minimum integer equal to or higher than real number b,
then, s and l are expressed by equation (1) and equation (2) below respectively;
$$\begin{matrix}s ≧ \{ \begin{matrix}ceiling ( \frac{α - 1}{2 \cdot ( k - 1 )} ) , & if r = 2 \\ ceiling ( \frac{α}{rk - 1} ) and & k > \frac{1}{r} , else\end{matrix} & ( 1 ) \\ l = \{ \begin{matrix}ceiling ( \frac{α + 2 s - 1}{2} ) , & if r = 2 \\ \frac{α + s}{r} , & else\end{matrix} & ( 2 )\end{matrix}$$
and said traceback circuit executes one traceback processing operation for (T+skx) by taking a time equivalent to l clocks, thereby outputting a decoding result of skx bits.

3. The decoding apparatus according to claim 2, wherein depth a of a RAM, which stands for Random Access Memory, configuring said path memory is represented by equation (3);
$$a = α + s + ceiling ( \frac{l}{k} ) - 1. \qquad ( 3 )$$

4. The decoding apparatus according to claim 2, wherein, if r≦1 and s=1, then said path memory is configured by a single-port RAM.

5. The decoding apparatus according to claim 1, wherein:
a traceback length of said two traceback circuits is represented by positive integer T divisible by kx;
the number of clocks necessary for one traceback processing operation is represented by l in the case where next traceback processing is started every s times said path select information is written to said path memory;
α=T/(kx);
u is a positive integer satisfying u≦s; and
ceiling (b) represents a minimum integer equal to or higher than real number b,
then, s and l are expressed by equation (4) and equation (5) below respectively;
$$\begin{matrix}s ≧ ( \frac{α - r \cdot \{ ( k - 1 ) \cdot u + 1 \}}{rk - 1} ) and k > \frac{1}{r} and r ≦ 1 & ( 4 ) \\ l = \frac{α + s}{r} + u - 1 & ( 5 )\end{matrix}$$
and said traceback circuit executes one traceback processing operation for (T+skx) by taking a time equivalent to l clocks, thereby outputting a decoding result of skx bits.

6. The decoding apparatus according to claim 5, wherein depth a of a RAM, which stands for Random Access Memory, configuring said path memory is represented by equation (6);
$$a = α + s + ceiling ( \frac{l}{k} ) - 1. \qquad ( 6 )$$

7. The decoding apparatus according to claim 1, wherein, if r=2 or the number of said traceback circuits is two, said path memory is configured by a dual-port RAM having two read ports.

8. The decoding apparatus according to claim 1, wherein said path memory is configured by a RAM that executes an operation of outputting write information written immediately before from a read port at a time next to a time at which writing was executed.

9. The decoding apparatus according to claim 1, wherein a value of m is restricted with a maximum value of m being m_{fc} and, for values of k and r, values satisfying m≦m_{fc} are used.

10. The decoding apparatus according to claim 1, wherein, for values of k and r, values are used that minimize a sum of a circuit scale of said shift register and a circuit scale of a RAM for use in said path memory.

11. The decoding apparatus according to claim 10, wherein, for values of k and r, values are used that minimize a sum of a circuit scale of said shift register, a circuit scale of a RAM for use in said path memory, and a circuit scale of a flip-flop for holding information read from said path memory arranged in a module including said traceback circuit.

12. The decoding apparatus according to claim 1, wherein said sift register is a pretraceback circuit of k stages.

13. A decoding method comprising the steps of:
with N and x each being a positive integer and k being a positive integer being equal to or greater than 1,
accumulating, by a shift register of k stages, path select information for k inputs that is information about a survivor path of xN bits made up of radix-2^{x} in each transient state of a convolutional code of the number of states N;
storing, by a path memory having one bank, at one address, said path select information for k inputs accumulated in said shift register; and
tracing back, by a traceback circuit, paths for m=rkx time in one clock by use of said path select information read from said path memory with t being a divisor of kx and r being 2 or 1/t.
